(19) United States
(12) Patent Application Publication
(10) Pub. No.: US 2024/0411944 A1
(43) Pub. Date: Dec. 12, 2024

(54) SYSTEM FOR OPTIMIZING INSPECTION LOCATIONS IN A FACILITY

(71) Applicant: Visionaize Inc., San Jose, CA (US)

(72) Inventor: David Reinhart, San Jose, CA (US)

(21) Appl. No.: 18/330,482

(22) Filed: Jun. 7, 2023

(51) Int. Cl. G06F 30/13

(52) U.S. Cl. CPC G06F 30/13; G06F 30/20; G06Q 10/06

(57) ABSTRACT

System and method for determining optimized inspection locations of physical objects in a facility are described. In one aspect, number of inspection locations, type of inspections and corresponding positions of the inspection locations in a virtual model are determined based on multiple guidelines or predefined rules and multiple inspection variables associated with the physical objects. Based on the virtual assets adjacent to the virtual model, an accessibility index of each inspection location, and parameters associated with the multiple guidelines or predefined rules, multiple recommendations including an optimized number of inspection locations and the corresponding positions of the inspection locations, represented as a plurality of marked points, is generated. The generated recommendations are rendered on a display associated with a client device. A physical inspection of the one or more physical objects is planned and executed based on the plurality of marked points.

### FIELD

Various embodiments of the disclosure relate to an inspection processing system. More specifically, various embodiments of the disclosure relate to a system and method for determining optimized number and positions of inspection locations associated with physical objects in a facility.

### BACKGROUND

Physical objects in large or complex facilities may require proper health monitoring, such as a planned schedule for conducting an inspection, maintenance, and repair, for an enhanced operational performance and extended life span of such physical objects. For inspecting the physical objects in such large or complex facilities, information with reference to, for example, a timing and specific locations of inspection points or points-of-interest (POIs) may be required. The inspection of the physical objects in the complex facilities may follow specific standards (or requirements) which may be established based on operational requirements of the facility. Other benchmark and regulatory requirements may be also considered when establishing the standards for inspecting the facilities.

Conventional systems may implement mechanisms that may be redundant and cumbersome. For example, quantity and location of the inspection points may involve manually locating the points of interest or inspection points based on established standards. Further, the inspection points may be stored as two-dimensional (2D) drawings, for example, Isometrics, Engineering Plans, or General Arrangement drawings. The inspection points and a corresponding data may be updated and maintained by a responsible party, such as an inspection department. The inspection points may be documented and monitored on a regular basis and additional inspection points may be added, based on a determination by the inspection department. The inspection points may initially be defined using the standards and preferences based on experience and are subsequently modified over time based on demand.

Locating such inspection points may be a challenge for personnel, such as an expert practitioner or a human technician. For example, planning the inspection and subsequently conducting the inspection, due to the timing and volume of inspections typically required in complex facilities may further add to the challenges. In certain scenarios, various parts of the physical objects, such as blades of a turbine or a tower of a gas flare, may be inaccessible and/or extremely risky for the personnel. In other scenarios, the location of the physical asset, for example an ocean, a desert area, or an underground area, may not be comfortable for the personnel to plan and conduct any physical inspection. Therefore, manual locating the inspection points in above-described scenarios, without compromising an inspection quality and reliability, may be challenging.

The limitations and disadvantages of conventional and traditional approaches will become apparent to one of skill in the art, through comparison of described systems with some aspects of the present disclosure, as set forth in the remainder of the present application and with reference to the drawings.

### SUMMARY

A system and a method for determining optimized number and positions of inspection locations corresponding to physical objects in a facility. The system may include a memory for storing instructions and a processor configured to execute the instructions. Based on a plurality of predefined rules and a plurality of inspection variables associated with one or more physical objects in a facility, the processor may be further configured to determine a number of inspection locations in a virtual model. The virtual model includes a plurality of virtual assets that is generated based on a 3-dimensional (3D) modeling of the facility. For the determined number of inspection locations, the processor may be further configured to determine one or more types of inspections and one or more corresponding positions of the inspection locations based on the plurality of predefined rules and the plurality of inspection variables. Based on one or more virtual assets adjacent to the virtual model, an accessibility index of each inspection location, and a plurality of parameters associated with the plurality of predefined rules, the processor may be further configured to generate a plurality of recommendations including an optimized number of inspection locations and the corresponding one or more positions of the inspection locations. The processor may be further configured to render, at a display associated with a client device, the generated plurality of recommendations including the optimized number of inspection locations and the corresponding one or more positions of the inspection locations represented as a plurality of marked points. A physical inspection of the one or more physical objects is planned and executed based on the plurality of marked points.

These and other features and advantages of the present disclosure may be appreciated from a review of the following detailed description of the present disclosure, along with the accompanying figures in which like reference numerals refer to like parts throughout.

### BRIEF DESCRIPTION OF THE DRAWINGS

FIG. 1 is a block diagram showing an exemplary network environment of a system to implement components for determining optimized number and positions of inspection locations corresponding to physical objects in a facility, according to exemplary embodiments.

FIG. 2 shows an exemplary inspection processing system for determining optimized number and positions of inspection locations corresponding to physical objects in a facility, according to exemplary embodiments.

FIGS. 3A, 3B, and 3C are illustrations showing exemplary user interfaces of different scenarios for determining optimized number and positions of inspection locations corresponding to physical objects in a facility, according to exemplary embodiments.

FIGS. 4A and 4B show flowcharts collectively depicting a method that includes operational steps for determining optimized number and positions of inspection locations corresponding to physical objects in a facility, according to exemplary embodiments.

FIG. 5 shows an exemplary hardware configuration of computer that may be used to implement components of a system for determining optimized number and positions of inspection locations corresponding to physical objects in a facility, according to exemplary embodiments.

### DETAILED DESCRIPTION

Various embodiments of the disclosure relate to a system and method for determining optimized number and positions of inspection locations associated with physical objects in a facility. The system and method may enable inspecting locations based on factors, such as relative location, accessibility, and timing, when planning and implementing inspection of specific POIs. The automated or semi-automated placement, verification, and review of such inspection locations associated with the physical objects may provide technical advantages, for example, meeting compliance requirements with standards or guidelines or predefined rules, and efficient and non-redundant planning and execution of the physical inspection. As the inspection locations are non-staggered, the described system and method may provide enhanced accessibility and limited scaffolding requirements. Thus, such placement of the inspection points may be optimized across the facility, which may substantially improve the inspection quality, and reliability of the inspection process.

In an embodiment, a system may be provided that may include a memory for storing instructions, and a processor configured to execute the instructions. The system may execute operations to determine a number of inspection locations in a virtual model. For instance, the inspection locations may be determined based on multiple guidelines or predefined rules and inspection variables associated with one or more physical objects in a facility. The virtual model corresponding to the plurality of virtual assets may be generated based on a 3-dimensional (3D) modeling of a facility. For the determined number of inspection locations, the system may further be configured to determine one or more types of inspections and one or more corresponding positions of the inspection locations, for example, based on the plurality of guidelines or predefined rules and the plurality of inspection variables. Based on one or more virtual assets adjacent to the virtual model, an accessibility index of each inspection location, and multiple parameters associated with the plurality of guidelines or predefined rules, the system may be further configured to generate multiple recommendations including an optimized number of inspection locations and the corresponding one or more positions of the inspection locations. The system may further be configured to render, at a display device associated with a client device, the generated plurality of recommendations including the optimized number of inspection locations and the corresponding one or more positions of the inspection locations represented as multiple marked points. Physical inspection of the one or more physical objects may be planned and executed based on the plurality of marked points.

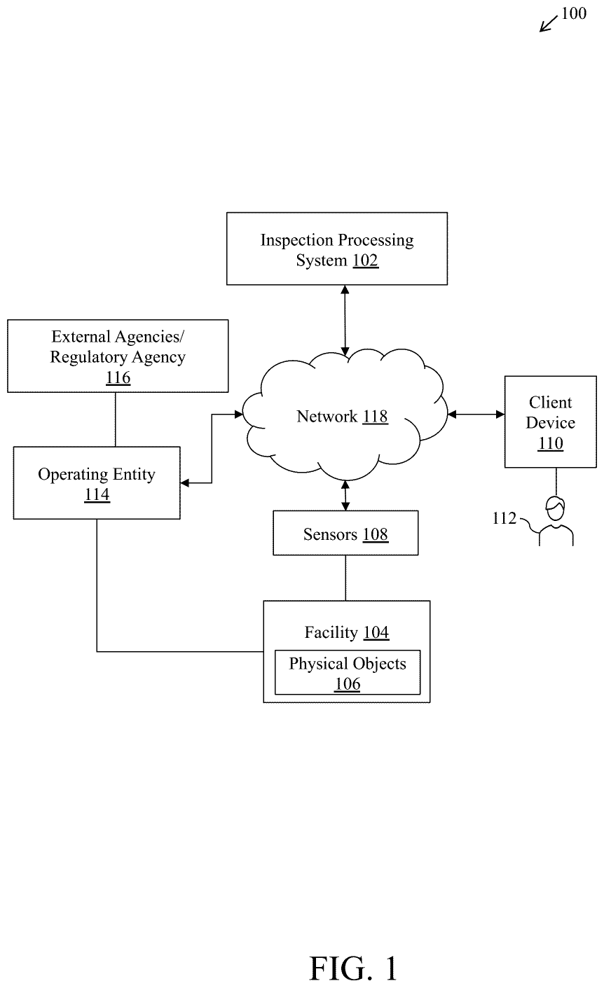

FIG. 1 is a block diagram showing an exemplary environment of a system to implement components for determining optimized number and positions of inspection locations corresponding to physical objects in a facility, according to exemplary embodiments. In an embodiment, a network environment 100 shown may include a communicatively coupled arrangement of an inspection processing system 102, a facility 104, one or more physical objects 106, sensors 108, a client device 110, a user 112 associated with the client device 110, an operating entity 114, an external agency/regulatory agency 116, and a network 118.

It should be noted that in accordance with different embodiments, different components of the network environment 100 may execute corresponding operations or functions may be partially or fully implemented by various cloud resources as an integrated or a distributed platform.

The inspection processing system 102 may include suitable logic, circuitry, and interfaces that may execute operations to implement a mechanism for performing an inspection. For example, the mechanism for inspection may include execution of operations for health monitoring, repairing, remediation, or improvement of the one or more physical objects 106. The above-described operations may be implemented as an automated or semi-automated mechanisms with limited or no human support. In an embodiment, the inspection processing system 102 may execute operations to determine an optimized number and positions of inspection locations corresponding to the one or more physical objects 106 in the facility 104.

The computing functionalities of the inspection processing system 102 may be implemented by physical electronic components and any software and/or firmware which may configure the hardware, be executed by the hardware, and/or otherwise be associated with the hardware. For example, the physical electronic components may include hardware, such as one or more silicon cores in a reduced instruction set computing (RISC) processor, an Application Specific Integrated Circuit (ASIC), a complex instruction set computing (CISC) processor, a Field Programmable Gate Array (FPGA), graphics processors, matrix processors, emulated or virtual machine processor, and other semiconductor chips, processors, control circuits, or a combination thereof. The software and/or firmware may include code, microcode, instruction set or logic elements that are executable by the physical electronic components.

The facility 104 may correspond to a structure that is disposed at a geographical location and associated with the operating entity 114. The facility 104 may have multiple objects, i.e., the one or more physical objects 106, that may facilitate in performing various tasks based on business/industrial operations defined by the operating entity 114. Examples of the facility 104 may include, for example, a refinery, a chemical plant, a building, a manufacturing unit, a dam, a bridge, a harbour, a railway facility, an underground facility, etc.

The one or more physical objects 106 may correspond to physical assets disposed in the facility 104. The one or more physical objects 106 may execute operations associated with various tasks for running business/industrial operations defined by the operating entity 114. The one or more physical objects 106 may be subjected to inspection by the inspection processing system 102 with reduced time and costs and also improved accuracy. The one or more physical objects 106 may include distributed objects (such as a pipeline, an electrical grid, and a bridge) or discrete objects (such as a tower, a wind turbine, a gas flare, drilling/mining equipment, and a locomotive).

In an embodiment, the one or more physical objects 106, such as mechanical process systems, may be deployed in discrete and complex facilities (such as manufacturing, chemical, oil and gas, and energy facilities). For example, in a refinery or a chemical plant, the one or more physical objects 106 may correspond to piping and equipment, and process equipment with gas detectors. In another example, in special devices, such as helicopters, relatively small power plants, jets, and tanks, the one or more physical objects 106 may correspond to gas turbines.

The sensors 108 may include suitable logic, circuitry, and interfaces that may execute operations to detect and record digital data describing actual mechanical condition of each of the one or more physical objects 106. The sensors 108 may further detect (or sense) information about the user 112 (associated with the client device 110) and the surrounding environment around the inspection processing system 102. Examples of the sensors 108 may include, for example, an acceleration sensor, a gyroscope, a compass, a global positioning system (GPS), a haptic sensor (e.g., touchscreen and buttons), a microphone, a proximity sensor, an illuminance sensor, a magnetic sensor, an mmWave sensor, a gravity sensor, a motion sensor, an RGB sensor, an infrared sensor, an ultrasonic sensor, a battery gauge, camera, and the like. The sensors 108 may further include biometric sensors, such as retina scanner, fingerprint and thumbprint scan sensor, optical scanner, the microphone, to detect biometric data of the user 112. Combining the outputs of various sensors may therefore provide more robust determination of the mechanical condition of each of the one or more physical objects 106.

The client device 110 may include suitable logic, circuitry, and interfaces that may execute operations to provide input to the inspection processing system 102 and display output received from the inspection processing system 102. Numerous examples of the client device 110 may include, for example, a smartphone, a tablet personal computer (PC), a slate PC, a personal digital assistant (PDA), an Ultrabook, a wearable electronic device (such as smart clothing, head-mounted display (HMD), or smart glasses), a smart television, a desktop computer, a laptop computer, and other such electronic devices and Internet Protocol (IP) appliances.

In an embodiment, the client device 110 may execute operations to download an application program, referred to as an “app”, that facilitates a variety of functionalities for the user 112. Examples of such functionalities may include enabling various modes of electronic communication between the inspection processing system 102 and the client device 110.

For certain instances of the client device 110, such as desktop and laptop computers, the application program may correspond to desktop apps. For other instances of the client device 110, such as smartphones, the application program may correspond to mobile apps. The mobile apps may be of three basic types, i.e., native apps, web apps, and hybrid apps. The native apps may be standalone apps that are downloaded and installed at the client device 110. The native apps are built just for one specific platform or operating system, such as Android® and iOS®. The web apps may be accessed via a web browser and are responsive versions of websites. The web apps may have limited functionalities due to an extensive dependence on the web browser used by the client device 110. The hybrid apps are a combination of native and web apps, i.e., web apps with a native app shell. The hybrid apps may have a home screen app icon, some responsive design and may even work offline.

In an embodiment, the client device 110 may execute operations as a thin or an ultra-thin client enabling remote desktop applications. In such embodiment, application software may be allowed to run on a centrally hosted virtual computing system, such as the inspection processing system 102. Such thin or ultra-thin client may rely on access to the inspection processing system 102 each time input data needs to be processed or validated. The client device 110 may provide an infrastructure to enable the downloading of various application programs and may facilitate browsing of various online platforms.

The operating entity 114 may correspond to an individual, an enterprise, or an organization that holds an ownership of a business unit. The operating entity 114 may act as a stakeholder in the regular business and manage operational processes and systems. In accordance with different scenarios, the operating entity 114 may be an owner of the facility 104 and/or manage the facility 104.

The external agency/regulatory agency 116 may correspond to an independent body established to set standards in a specific field of activity or operations and thereafter, to enforce such standards. Regulatory powers of the external agency/regulatory agency 116 may ensure that individuals, such as the user 112, and the industry, such as the operating entity 114, comply with legislative requirements, and further respond to instances of non-compliance. Non-limiting examples of the external agency/regulatory agency 116 may include Bureau of Safety and Environmental Enforcement (BSEE) and the Environmental Protection Agency (EPA). BSEE is responsible for enforcing safety and environmental regulations of offshore oil and gas resources. On the other hand, EPA regulates the production and distribution of commercial and industrial chemicals, in order to ensure that chemicals for sale and use in the United States do not harm human health or the environment.

The network 118 may include suitable logic, circuitry, and interfaces that may execute operations to facilitate communication between different components, systems and/or sub-systems of the network environment 100. In various embodiments, the network environment 100 may be implemented using any number or type of communication networks. The network 118 may execute operations to provide multiple network ports and multiple communication channels for transmission and reception of communication data. Each network port may correspond to a virtual address (or a physical machine address) for transmission and reception of the communication data. For example, the virtual address may be an Internet Protocol version 4 (IPV4) or an Internet Protocol version 6 (IPV6) address, and the physical address may be a media access control (MAC) address. The communication data may be transmitted or received via a communication protocol, the examples of which may include, for example, a short-range communication protocol, a Hypertext Transfer Protocol (HTTP), a File Transfer Protocol (FTP), a Simple Mail Transfer Protocol (SMTP), a Domain Name Server (DNS) protocol, and a Common Management Information Protocol (CMIP) Over Transmission Control Protocol/Internet Protocol TCP/IP (CMOT).

The communication data may be transmitted or received via at least one communication channel of multiple communication channels. The communication channels may include, for example, a wireless channel, a wired channel, or a combination of wireless and wired channel thereof. The wireless or wired channel may be associated with a data standard which may be defined by one of a Local Area Network (LAN), a Personal Area Network (PAN), a wireless personal LAN (WPLAN), a Wireless Local Area Network (WLAN), a Wireless Sensor Network (WSN), a WAN, and a Wireless Wide Area Network (WWAN), the Internet, cellular networks, Wireless Fidelity (Wi-Fi) networks, short-range networks (for example, Bluetooth® or ZigBee®), and/or any other wired or wireless communication networks or mediums. In an embodiment, the wired channel may be selected based on the bandwidth criteria. For example, an optical fibre channel may be used for a high bandwidth communication, and a coaxial cable (or Ethernet-based communication channel) may be used for moderate bandwidth communication. In accordance with various embodiments, any, some, combination, or all of the systems, units, engines, and/or sub-systems of the network environment 100 may be adapted to execute any operating system, such as Linux-based operating systems, UNIX-based operating systems, Microsoft Windows, Windows Server, MacOS, Apple IOS, Google Android, or other customized and/or proprietary operating system. The systems, units, engines, and/or sub-systems of the network environment 100 may be adapted to execute such operating systems along with virtual machines adapted to virtualize execution of a particular operating system.

It should be noted that FIG. 1 is described herein as containing or being associated with multiple devices, systems and/or sub-systems. Nevertheless, not all the devices, systems and/or sub-systems illustrated in the network environment 100 of FIG. 1 may be utilized in each alternative implementation of the present disclosure. Additionally, one or more of the devices, systems and/or sub-systems described in connection with the examples of FIG. 1 may be located external to network environment 100. Further, certain systems and/or sub-systems illustrated in FIG. 1 may be combined with other components, as well as used for alternative or additional purposes in addition to those purposes described herein. Furthermore, certain devices, systems and/or sub-systems illustrated in FIG. 1 may operate as standalone devices or may be integrated with, embedded in, or attached to one another. Accordingly, it should be noted that the network environment 100 of FIG. 1 may be implemented with any aspect of the various embodiments described throughout this disclosure.

In operation, the inspection processing system 102 may execute operations to receive data including multiple virtual assets corresponding to the one or more physical objects 106 of the facility 104. The data corresponding to the plurality of virtual assets is generated based on a 3D modeling of the facility 104. Based on multiple guidelines or predefined rules and inspection variables associated with the one or more physical objects 106, the inspection processing system 102 may be further configured to determine a number of inspection locations at the facility 104. The plurality of predefined rules may correspond to various guidelines or standard operating procedures that may be established based on an operational requirement of the facility 104. In accordance with an embodiment, the plurality of predefined rules may be managed by one of the external agencies/regulatory agencies 116. In accordance with another embodiment, the plurality of guidelines or predefined rules may be provided by the operating entity 114. In accordance with yet another embodiment, the plurality of predefined rules may be provided by both the operating entity 114 and the external agency/regulatory agency 116. For the determined number of inspection locations, the inspection processing system 102 may be further configured to determine one or more type of inspections and one or more corresponding positions of the inspection locations based on the plurality of guidelines or predefined rules and the plurality of inspection variables.

The inspection processing system 102 may be further configured to generate multiple recommendations including an optimized number of inspection locations and the corresponding one or more positions of the inspection locations. The plurality of recommendations may be generated based on one or more virtual assets adjacent to the virtual model, an accessibility index of each inspection location, and multiple parameters associated with the plurality of guidelines or predefined rules. The inspection processing system 102 may be further configured to render the generated plurality of recommendations at the client device 110 at a display device associated with the client device 110. The rendered recommendations may include the optimized number of inspection locations and the corresponding one or more positions of the inspection locations represented as multiple marked points. A physical inspection of the one or more physical objects is planned and executed based on the plurality of marked points at the client device 110.

In an embodiment, the inspection processing system 102 may execute operations to apply the plurality of guidelines or predefined rules to the existing inspection locations. The plurality of guidelines or predefined rules may be used for review and the optimization of new or existing inspection locations for the one or more virtual assets. The inspection processing system 102 may verify whether at least one of the inspection locations or existing inspection locations match or deviate from the plurality of guidelines or predefined rules. Accordingly, the inspection processing system 102 may generate a report that includes one or more deviations from the plurality of guidelines or predefined rules for the at least one of the inspection locations or the existing inspection locations. The inspection processing system 102 may further generate a recommendation for a compliance with the plurality of predefined rules and the plurality of inspection variables.

In an embodiment, the inspection processing system 102 may be further configured to generate a simulation model corresponding to the one or more physical objects 106 in the facility 104. In an embodiment, the simulation model may be generated based on a user input provided by the user 112 at the client device 110. The user input may include a selection of one of the rendered plurality of recommendations and one or more user preferences provided by the user 112.

In an embodiment, the method implementing the inspection processing system 102 may apply the plurality of guidelines or predefined rules (which may be user-defined or pre-defined) to automate or semi-automate the naming and physical placement of inspection locations or other rule-based discrete locations in a virtual model corresponding to the plurality of virtual assets in the facility 104. For example, the method may automate the placement or physical inspection location corrosion monitoring locations (CMLs), thickness monitoring locations (TMLs), or any other type of inspection locations on mechanical process systems (for example, piping and equipment) by applying the plurality of guidelines or predefined rules for inspecting mechanical process systems. The method may further provide confirmation or verification that already placed inspection locations match or deviate from the plurality of guidelines or predefined rules. Further, based on accessibility and relative vicinity to other inspection locations, the method may further optimize or minimize the number and inspection locations placed on mechanical process systems based on the plurality of guidelines or predefined rules.

In an embodiment, the method implementing the inspection processing system 102 may apply the plurality of guidelines or predefined rules and inspection variables to already placed inspection locations in the virtual model of the one or more physical objects 106 in the facility 104. The inspection processing system 102 may present the user 112 with compliance with (or divergence from) the plurality of guidelines or predefined rules and inspection variables. Deviations from the plurality of guidelines or predefined rules may be reported and recommendations to comply with plurality of guidelines or predefined rules and variables may be presented. The quantity and optimization of the inspection locations may also be recommended as described above.

In an embodiment, the inspection processing system may provide and implement decision-based logic, multiple interfaces, engines and/or models, frameworks, one or more circuitries and/or code executable by the circuitries. The engines and/or models, frameworks, implemented by the inspection processing system may execute operations either independently or in cooperation. An engine may correspond to a special purpose program or an executable code that performs or executes one or more core functions or operations. The engine may be continually trained by multiple data sources in real time or based on a historical information or data. The engine may be implemented as artificial intelligence engines or models or machine learning engines or models.

In an embodiment, modelling may correspond to a mechanism or a process that includes creating or improvising a functional or operational aspect of a system or one or more features of the system by referencing an existing or known knowledge base. The outcome of the modelling process may simplify the functional or operational aspect of the inspection processing system or one or more features of the inspection processing system that may be easily understood, quantified, and visualized. The mechanism for modelling may be automated through a continual process of training the model with data from multiple sources or data sources. The engines and/or the models may implement an execution of the one or more core functions or operations based on configured one or more rules, one or more guidelines or predefined rules and/or one or more sequence of sequence of steps to produce specific outcomes. The engines and/or models may execute operations to work either independently or in conjunction with one or more engines or one or more models.

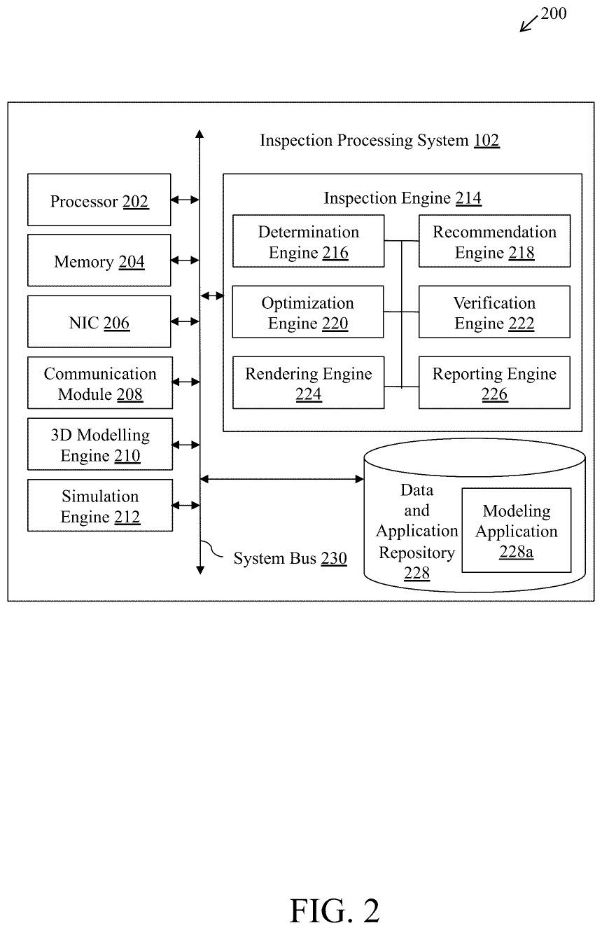

FIG. 2 shows an exemplary inspection processing system for determining optimized number and positions of inspection locations corresponding to physical objects in a facility, according to exemplary embodiments. A schematic representation 200 of FIG. 2 may include various components, such as a processor 202, a memory 204, a network interface controller (NIC) 206, a communication module 208, and multiple individual processing engines, such as a 3D modelling engine 210, a simulation engine 212, and an inspection engine 214 hosted on the inspection processing system 102 of FIG. 1. The inspection engine 214 may further include a determination engine 216, a recommendation engine 218, an optimization engine 220, a verification engine 222, a rendering engine 224, and a reporting engine 226. The inspection processing system 102 may further include a data and application repository 228. The various components of the inspection processing system 102 may be adapted for cooperation and communication with each other, using corresponding signal lines, by a system bus 230.

In accordance with different embodiments, different components of the inspection processing system 102 may execute corresponding operations or functionalities may be partially or fully implemented by various cloud resources as an integrated or a distributed platform. In an embodiment, the plurality of individual processing engines may be implemented on a single server, such as the inspection processing system 102, as shown in the schematic representation 200 of FIG. 2. In another embodiment, the plurality of individual processing engines may be distributed on more than one server as independent entities providing functionalities for which the individual distributed processing engines have been programmed. In such embodiment, communication between the individual distributed processing engines may be implemented through function calls managed by a distributed message exchange platform (not shown). The plurality of distributed processing engines may be used in parallel or sequentially in the network 118 to create synergies with each other.

The processor 202 includes an arithmetic logic unit, a microprocessor, a general-purpose controller, or some other processor array to perform computations and determine an executable operation of the inspection processing system 102 based on executable instructions stored in the memory 204 or commands provided by the user 112. It should be noted that the terms “processor” or “microprocessor” include not only a traditional microprocessor (such as Intel's® industry-leading x86 and x64 architectures), but also graphics processors, matrix processors, a CISC, a RISC, ASIC, FPGA, microcontroller, digital signal processor (DSP), programmable logic device, programmable logic array (PLA), microcode, instruction set, emulated or virtual machine processor, or any similar device, combination of devices, or logic elements (hardware or software) that permit the execution of instructions.

The memory 204 stores instructions and/or data that may be accessed by one or more processors, such as the processor 202. The instructions and/or data may include code which when executed by the one or more processors, the one or more processors may execute operations to perform the techniques and method steps described herein. The memory 204 may be, for example, a dynamic random-access memory (DRAM) device, a static random-access memory (SRAM) device, flash memory, or some other memory device. In some embodiments, the memory 204 may also include a non-volatile memory or similar permanent storage device and media including a hard disk drive, a floppy disk drive, a CD-ROM device, a DVD-ROM device, a DVD-RAM device, a DVD-RW device, a flash memory device, or some other mass storage device for storing information, instructions and/or data on a more permanent basis. A portion of the memory 204 may be reserved for use as a buffer or virtual random-access memory (virtual RAM).

The NIC 206 may execute operations to transmit and receive data to and from the network 118. In an embodiment, the NIC 206 may include a port for direct physical connection to the network 118 or to another communication channel. For example, the NIC 206 may include a USB, SD. CAT-5, or similar port for wired communication with the network 118. In accordance with another embodiment, the NIC 206 may include a wireless transceiver for exchanging data with the network 118 or other communication channels using one or more wireless communication methods, including: IEEE 802.11; IEEE 802.16, BLUETOOTH®, or another suitable wireless communication method. In accordance with another embodiment, the NIC 206 may include a Direct Short-Range Communication (DSRC) transceiver, a DSRC receiver and other hardware or software necessary to make the inspection processing system 102 a DSRC-enabled device.

In accordance with another embodiment, the NIC 206 may include a cellular communications transceiver for sending and receiving data over a cellular communications network including via short messaging service (SMS), multimedia messaging service (MMS), hypertext transfer protocol (HTTP), direct data connection, WAP, e-mail, or another suitable type of electronic communication. In accordance with another embodiment, the NIC 206 may include a wired port and a wireless transceiver. The NIC 206 may also provide other conventional connections to the network 118 for distribution of files or media objects using standard network protocols including TCP/IP, HTTP, HTTPS, and SMTP, millimeter wave, DSRC, and the like.

The communication module 208 may be software including routines for handling communication between the inspection processing system 102 and other components of the network environment 100. In some embodiments, the communication module 208 may be a set of instructions executable by the processor 202 to provide the functionality described below for handling communications between the inspection processing system 102 and other components of the network environment 100.

The communication module 208 may send and receive digital data and messages, via the NIC 206, to and from one or more elements, such as the sensors 108, the client device 110, the operating entity 114, and the external agency/regulatory agency 116, of the network environment 100. Such received data and messages, such as the inspection data, the variable and attribute data, and the data tables, may be stored in the data and application repository 228 of the inspection processing system 102.

In an embodiment, the communication module 208 may receive digital data from various components of the inspection processing system 102 and store the digital data in the data and application repository 228 of the inspection processing system 102. The communication module 208 may transmit the digital data to the 3D modelling engine 210 for generating digital twin data, i.e., the virtual model, corresponding to the one or more physical objects 106 in the facility 104. The communication module 208 may further store an updated version of the digital twin data, i.e., an updated virtual model, in the data and application repository 228 corresponding to updated digital data and messages received from the one or more elements, such as the sensors 108, the client device 110, the operating entity 114, and the external agency/regulatory agency 116, of the network environment 100.

In an embodiment, the communication module 208 may handle communication between components of the inspection processing system 102. For example, the communication module 208 may receive the factory virtual model or the updated virtual model from the 3D modelling engine 210 and transmit the factory virtual model or the updated virtual model to the determination engine 216 to generate attribute data, such as number, types and positions of inspection locations in the virtual model or the updated virtual model. The communication module 208 may receive the attribute data from the determination engine 216 and transmit the attribute data to the recommendation engine 218 or the optimization engine 220. The recommendation engine 218 may determine recommendation data that corresponds to inspection locations being predicted based on AI algorithms that are applied on the attribute data. The optimization engine 220 may determine optimized data that corresponds to a minimum number of inspection locations based on various inspection variables from the attribute data. The communication module 208 may receive the recommendation data or the optimized data from the recommendation engine 218 or the optimization engine 220, respectively, and transmit the recommendation data or the optimized data to the verification engine 222. The verification engine 222 may determine verification data that corresponds to a match or a deviation of new, additional, or existing inspection locations from the plurality of predefined rules The communication module 208 may receive the verified data from the verification engine 222 and transmit the verified data to the rendering engine 224. The rendering engine 224 may determine rendering data that corresponds to multiple marked points in a graphical user interface (GUI) and a graphics scene with annotations to be rendered at a display device associated with the client device 110. The communication module 208 may receive the rendering data from the rendering engine 224 and transmit the rendering data with instructions to the NIC 206. The NIC 206 may further transmit the rendering data to the network 118.

In an embodiment, the communication module 208 may be stored in the memory 204 of the inspection processing system 102 and may be accessible and executable by the processor 202.

The 3D modelling engine 210 may include suitable logic, circuitry, and interfaces that may execute operations to generate a 3D virtual model of the one or more physical objects 106 located in the facility 104. In an embodiment, the data and application repository 228 may include a modeling application that includes code and routines that are executed by the processor 202 and/or the 3D modelling engine 210 to generate the 3D virtual model.

In an embodiment, the 3D virtual model may describe the hardware and software design of the one or more physical objects 106 in corresponding factory condition. In some embodiments, the modeling application generates the 3D virtual model based on the design of the one or more physical objects 106. The modeling application may receive the digital data pertaining to the one or more physical objects 106 and generate the factory digital twin data. The factory digital twin data may be based on the design of the one or more physical objects 106 described by the digital data without any depreciation events at an initial stage. The digital data may be derived from the plurality of guidelines or predefined rules corresponding to standard operating procedures that are established by the operating entity 114 based on an operational requirements of the facility 104 or managed by the external agency/regulatory agency 116. The digital data may be retrieved from a data set or inputted as one or more files to the inspection processing system 102 by the user 112.

In an embodiment, over time depreciation events may occur, for example, the one or more physical objects 106 may undergo wear-and-tear events over a period of time, the modeling application may generate a modified virtual model. The modified virtual model may be based on modification of the factory digital twin data based on the (initial or previous) factory digital twin data and cumulative instances of sensor data that are received from the sensors 108 for the one or more physical objects 106 as of a time (for example, a current time).

In an embodiment, the modeling application may generate the factory digital twin data and the modified digital twin data based on creating computational analytical models using the digital data and the sensor data. The computational analytical models may show operating effects, predict states, and determine behavior of each of the one or more physical objects 106. These computational analytical models may prescribe actions based on engineering simulations, statistics, machine learning, artificial intelligence, business logic or objectives.

The digital twin, i.e., the 3D virtual model, may be used to monitor the one or more physical objects 106, such as a wind turbine or oil pipeline, and reduce maintenance burdens. The digital twin may provide various benefits, such as increased reliability and availability through monitoring and simulation to improve performance, reduced risk of accidents and unplanned downtime through failure, lowered maintenance costs through predicting failure before occurrence, and unimpacted production goals due to scheduling maintenance, repair and the ordering of replacement parts.

The simulation engine 212 may include suitable logic, circuitry, and interfaces that when executed by the processor 202, in conjunction with the 3D modelling engine 210, may execute operations to generate a simulation model corresponding to the one or more physical objects 106 in the facility 104. In an embodiment, the simulation model may be generated based on a user input provided by the user 112 at the client device 110. The user input may include a selection of one of the rendered plurality of recommendations and one or more user preferences provided by the user 112. Such simulation model may accurately predict when the one or more physical objects 106 will be in a state to receive proactive maintenance before a breakdown event occurs, for example, a failed component.

In an embodiment, the simulation engine 212 may implement AI simulation using scenario data and asset data of other physical objects in the facility 104. The asset data of other physical objects may be retrieved from the sensors 108 and the data and application repository 228. The scenario data may correspond to information including risky scenarios that could not be tested in the real world, for example, a damaged physical object. The asset data of other physical objects may correspond to physical attributes, design specifications, and/or standard operating procedures of the other physical objects.

The simulation engine 212, in conjunction with the 3D modelling engine 210, may model a virtual world for the one or more physical objects 106 located in the facility 104 and engage in perception, path planning, and autonomous driving as it would operate in the real world. Software-in-the-loop and AI executing in the simulation engine 212 may control other physical objects that a simulated physical object from the one or more physical objects 106 might encounter. In an embodiment, the simulation engine 212 may execute operations to calculate the inspection costs for every recommended candidate solution.

The inspection engine 214 may include suitable logic, circuitry, and interfaces that may execute operations to utilize guidelines or predefined rules and subsequent inspection variables for calculating the number of inspection locations and automate (or recommend) placement of such inspection locations. Additionally, the inspection engine 214 may utilize adjacency and other factors to streamline or optimize the placement of such inspection locations. When guidelines or predefined rules are applied in the 3D digital twin environment by the inspection engine 214, the recommended inspection locations may require no change, thereby effectively reducing placement effort to near zero, while remaining in compliance with standards, and streamlining physical inspection activities.

The determination engine 216 may include suitable logic, circuitry, and interfaces that may execute operations to apply the plurality of guidelines or predefined rules to automate or semi-automate the naming and physical placement of inspection locations in the 3D virtual model. The determination engine 216 may determine the number, one or more type of inspections and one or more corresponding positions of the inspection locations in the virtual model.

The recommendation engine 218 may include suitable logic, circuitry, and interfaces that may execute operations to predict inspection locations based on AI algorithms, usually associated with machine learning. Such AI algorithms may be executed to provide an advanced data filtering system based on computer learning and statistical modeling by using a variety of data, for example, environmental data, the plurality of guidelines or predefined rules and inspection variables, usage data, factory data, sensor data, for such prediction.

In an embodiment, the recommendation engine 218 may generate multiple recommendations including an optimized number of inspection locations and the corresponding one or more positions of the inspection locations based on one or more virtual assets adjacent to the virtual model, an accessibility index of each inspection location, and multiple parameters associated with the multiple guidelines or predefined rules.

The optimization engine 220 may include suitable logic, circuitry, and interfaces that may execute operations to determine a minimum number of inspection locations to consider subsequent physical, visual, or other required inspections based on various inspection variables, such as inspection routing, one or more virtual assets adjacent to the virtual model, and an accessibility index of each inspection location. The optimization engine 220 may execute operations to determine the minimum or optimized number of inspection locations while meeting the plurality of guidelines or predefined rules.

The verification engine 222 may include suitable logic, circuitry, and interfaces that may execute operations to apply the plurality of guidelines or predefined rules to new, additional, or existing inspection locations inspection locations. More specifically, the verification engine 222 may execute operations to verify whether the new, additional, or existing inspection locations match or deviate from the plurality of guidelines or predefined rules. In one case, when the verification engine 222 verifies that the new, additional, or existing inspection locations deviate from the plurality of guidelines or predefined rules, a report may be generated that includes one or more deviations from the plurality of guidelines or predefined rules for existing inspection locations by the reporting engine 226. In other case, when the verification engine 222 verifies that the new, additional, or existing inspection locations match with the plurality of guidelines or predefined rules, multiple recommendations including the optimized number of inspection locations and the corresponding one or more positions of the inspection locations may be generated by the recommendation engine 218.

The rendering engine 224 may include suitable logic, circuitry, and interfaces that may execute operations to render, at a display device associated with the client device 110, multiple marked points in the GUI and a graphics scene with annotations. In an embodiment, the rendering engine 224 may operate in conjunction with the 3D modelling engine 210 to render the 3D virtual model including the plurality of marked points. The plurality of marked points may pertain to the generated plurality of recommendations including the optimized number of inspection locations and the corresponding one or more positions of the inspection locations. In accordance with another embodiment, the rendering engine 224 may operate in conjunction with the simulation engine 212 to render a simulated model of a virtual world corresponding to the one or more physical objects 106 in the facility 104. In an embodiment, the simulated model of the virtual world may correspond to a recommended candidate solution provided by the recommendation engine 218. The simulation model may be rendered based on the user input provided by the user 112. The user input may include a selection of one of the rendered plurality of recommendations and one or more user preferences.

The rendering engine 224 is graphical processing unit (GPU)-based and may consist of modules optimized to perform the computations and 3D computer graphics operations pertaining to, for example, lighting and shading of the plurality of virtual assets, in an enhanced photorealistic manner. The rendering data generated by the rendering engine 224 may be transmitted by the communication module 208 to the NIC 206, which further transmits the rendering data to the client device 110, via the network 118.

The reporting engine 226 may include suitable logic, circuitry, and interfaces that may execute operations to generate a report that includes one or more deviations from the plurality of guidelines or predefined rules for new, additional, or existing inspection locations. The one or more deviations may correspond to a positional deviation of the inspection locations, for example, an angular (or rotational) deviation, a missing inspection location, a similar or identical names of inspection locations (i.e., a different component being placed), different polarities (i.e., the polarity of the inspection location different from the polarity described in the plurality of guidelines or predefined rules), and the like. The one or more deviations may correspond to functional or operational deviation, for example, abnormal temperature, pressure, vibration, corresponding to each inspection location as described in the plurality of guidelines or predefined rules.

The data and application repository 228 may include suitable logic, circuitry, and interfaces that may execute operations to store various data values, data tables, messages, and applications. Such data values, data tables, messages, and applications may be utilized by various processing units of the inspection processing system 102 for determining optimized number and positions of inspection locations at the one or more physical objects 106 in the facility 104. In accordance with an embodiment, the data and application repository 228 may store a modeling application 228a that includes various code and routines. Such code and routines may be executed by the processor 202 and/or the 3D modelling engine 210 to generate the 3D virtual model. The data and application repository 228 may be implemented using various type of data storage technologies and standards, for example, ROM, RAM, DRAM, SRAM, SDRAM, magnetic random-access memory (MRAM), solid state, two and three-dimensional memories, Flash®, and other such memory devices.

In operation, the 3D modelling engine 210 may execute operations to generate the virtual model including the plurality of virtual assets corresponding to the one or more physical objects 106 of the facility 104. The virtual model may correspond to a 3D digital twin, which is a digitized version of the one or more physical objects 106 replicating the condition of the one or more physical objects 106 as well as individual components of the one or more physical objects 106, as indicated by the sensors 108. The 3D digital twin of the physical objects 106 accurately reflects the mechanical condition of the one or more physical objects 106 and whether parts of the one or more physical objects 106 will need to be replaced soon. The virtual model may be generated based on data received from the sensors 108 and the plurality of guidelines or predefined rules. The virtual model may be further generated based on multiple inspection variables for the virtual model received based on the plurality of guidelines or predefined rules. The plurality of inspection variables may be received individually as data values via a user interface or collectively as a data table. The virtual model may be further generated based on additional inspection variables corresponding to one or more attributes of the one or more physical objects 106.

In an embodiment, the plurality of guidelines or predefined rules may be received from one or more components of the network environment 100, such as the client device 110, the operating entity 114, and/or the external agencies/regulatory agency 116, via the network 118 and the NIC 206. The plurality of guidelines or predefined rules may correspond to standard operating procedures that may be established based on an operational requirement of the facility 104 and managed by one of the external agencies/regulatory agencies 116.

In an embodiment, the plurality of inspection variables may be received for the virtual model based on the plurality of guidelines or predefined rules. In another embodiment, the plurality of guidelines or predefined rules may be established, and plurality of inspection variables may be received individually as data values via a user interface or collectively as a data table into the data and application repository 228. For example, the plurality of guidelines or predefined rules may be entered as the inspection variables in, for example, V-Suite® software, by the user 112 at the inspection processing system 102 or the client device 110.

In an embodiment, the plurality of guidelines or predefined rules may be used for an automated placement of at least one of new inspection locations or additional inspection locations in the virtual model. In accordance with another embodiment, the plurality of guidelines or predefined rules may be used for a review and the optimization of new or existing inspection locations in the virtual model.

Examples of the new, additional, or existing inspection locations, may include, for example, thickness monitoring locations (TMLs), corrosion monitoring locations (CMLs) or Fugitive Emission type inspection points. However, it should be noted that the above examples should not be construed to be limiting, and guidelines or predefined rules for other type of fixed points may also be established in the plurality of guidelines or predefined rules and the plurality of inspection variables to facilitate point review, optimization, reduction, addition and/or placement of the inspection locations.

Examples of the plurality of guidelines or predefined rules and variables may include system or application program interface (API) classification, inspection location density by system classification (and component type), damage mechanisms, inspection circuit or loop category, inspection location naming convention, integrity operating window, injection point rules, dead leg(s), accessibility, and other pre-defined or custom variables, conflicts, and exceptions. Additional variables or asset attributes, for example, asset elevation (absolute and relative) may also be included.

In an embodiment, the 3D modelling engine 210 may execute operations to receive the virtual model including the plurality of virtual assets corresponding to the one or more physical objects 106 of the facility 104. The virtual model may be received by the 3D modelling engine 210 from an external device or modelling server. In an embodiment, the external device or modelling server may be communicatively coupled with the inspection processing system 102, via the network 118. The determination engine 216 may execute operations to determine whether placement of at least one of new inspection locations or additional inspection locations are to be determined or review of existing inspection locations is to be performed.

In case new inspection locations or additional inspection locations are to be determined, the determination engine 216 may execute operations to determine the number of inspection locations in the virtual model, based on the plurality of guidelines or predefined rules and the plurality of inspection variables associated with the one or more physical objects 106. The number of inspection locations may be determined based on an application of the plurality of guidelines or predefined rules to multiple inspection circuits or loops. The determination engine 216 may be further configured to determine one or more type of inspections and one or more corresponding positions of the inspection locations for the determined number of inspection locations based on the plurality of guidelines or predefined rules and the plurality of inspection variables.

In an embodiment, the number of inspection locations, one or more type of inspections and one or more positions of the inspection locations may be further determined based on additional variables, such as adjacency and other such factors (such as asset attributes), to facilitate a rapid inspection by geo-locating inspection locations ‘nearby’ or directly adjacent to other inspection locations. In an embodiment, the number of inspection locations, the one or more type of inspections and the one or more corresponding positions of the inspection locations may be determined based on an application of the plurality of guidelines or predefined rules to the plurality of inspection circuits or loops. Thus, the determination engine 216 may apply the plurality of guidelines or predefined rules to automate or semi-automate the naming and physical placement of inspection locations in the 3D virtual model.

The optimization engine 220 may execute operations to determine a minimum number of inspection locations to consider subsequent physical, visual, or other required inspections based on various inspection variables, such as inspection routing, one or more virtual assets adjacent to the virtual model, and an accessibility index of each inspection location. The optimization engine 220 may execute operations to determine the minimum or optimized number of inspection locations while meeting the plurality of guidelines or predefined rules.

The recommendation engine 218 may execute operations to determine a minimum or optimized number of inspection locations and the corresponding one or more positions of the inspection locations based on one or more virtual assets adjacent to the virtual model, an accessibility index of each inspection location, and multiple parameters associated with the plurality of guidelines or predefined rules.

In case existing inspection locations for the one or more virtual assets are to be reviewed and optimized, the verification engine 222 may execute operations to apply the plurality of guidelines or predefined rules to the existing or already placed inspection locations in the 3D virtual model. Additionally, the verification engine 222 may execute operations to apply the plurality of guidelines or predefined rules to the new inspection locations or additional inspection locations determined by the determination engine 216. Accordingly, the user 112 may be presented with compliance with or divergence of the new, additional, or existing inspection locations from the plurality of guidelines or predefined rules and the inspection variables.

In case the new, additional, or existing inspection locations deviate from the plurality of guidelines or predefined rules, the reporting engine 226 may execute to generate a report including one or more deviations. The one or more deviations may correspond to a positional, functional, or operational deviation, corresponding to each inspection location with respect to the plurality of guidelines or predefined rules. The generated report may be in a relevant format that, may itself be configurable by the user 112 for the user 112 to decide one or multiple times on an ongoing basis.

Further, the recommendation engine 218 may execute operations to generate a recommendation for an adherence or being compliant with the plurality of guidelines or predefined rules and the plurality of inspection variables. The generated recommendation may be rendered and displayed at the client device 110 for the user 112 to ensure that the planning and execution of the physical inspection is efficient and non-redundant.

In case the new, additional, or existing inspection locations match with the plurality of guidelines or predefined rules, the recommendation engine 218 may execute operations to generate the plurality of recommendations including the optimized number of inspection locations and the corresponding one or more positions of the inspection locations.

In an embodiment, the rendering engine 224 may execute operations to render the generated plurality of recommendations including the optimized number of inspection locations and the corresponding one or more positions of the inspection locations represented as multiple marked points.

In an embodiment, the processor 202 may receive a user input including the selection of one of the rendered plurality of recommendations and one or more user preferences. The user input may be received from the user 112 associated with a client device 110. In such case, the rendering engine 224, in conjunction with the 3D modelling engine 210 and the simulation engine 212, may execute operations to render a simulation model based on the received user input. The simulation model may be displayed at a display device associated with the client device 110 and provide various benefits, such as increased reliability and availability through monitoring and simulation to improve performance, access the risk of accidents and unplanned downtime through failure, estimate maintenance costs through predicting failure before occurrence, and assessment of production goals due to scheduling maintenance, repair and the ordering of replacement parts.

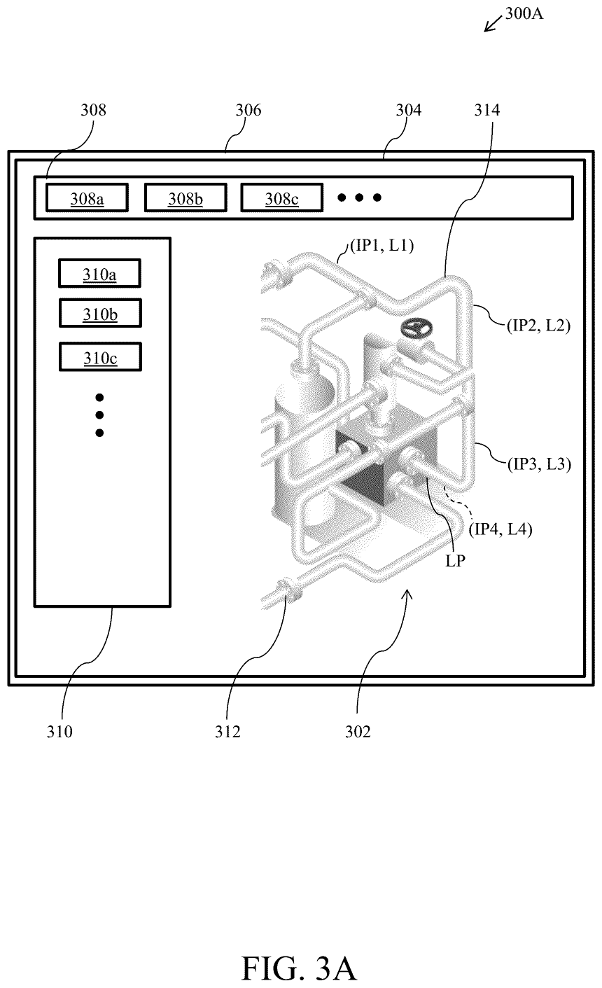

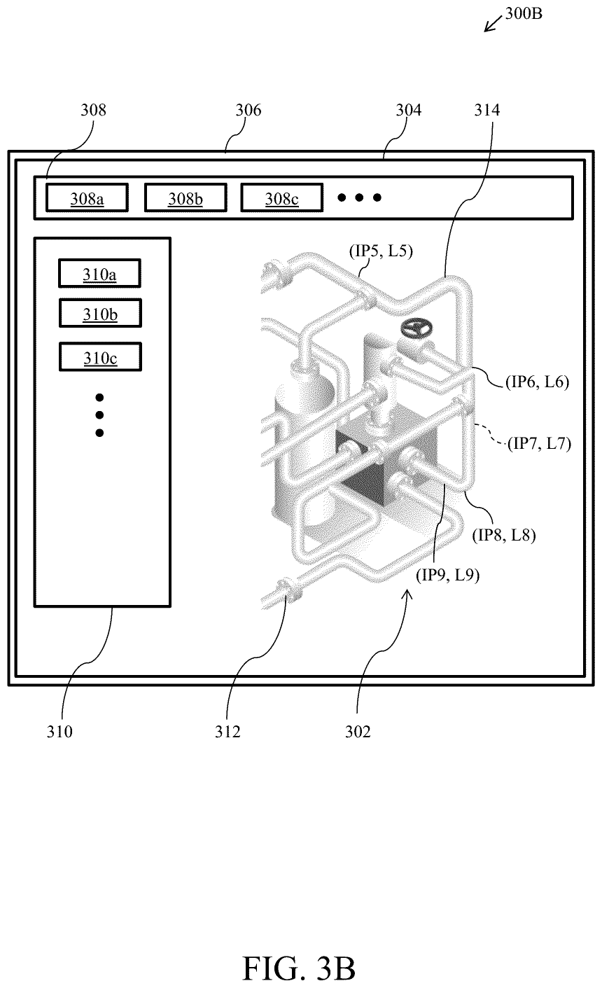

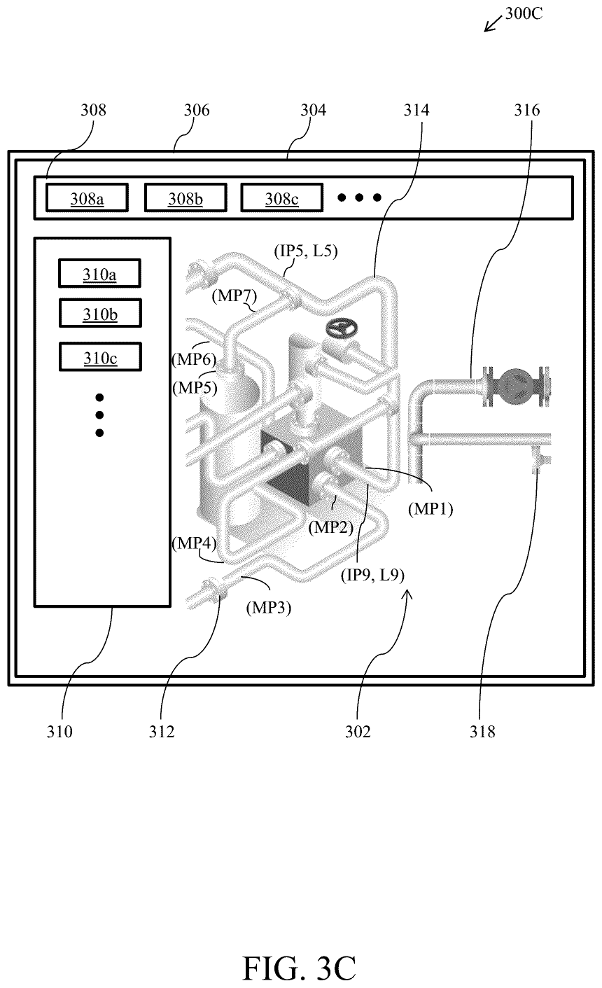

FIGS. 3A, 3B, and 3C are illustrations showing exemplary user interfaces of different scenarios, for determining optimized number and positions of inspection locations of the physical objects in a facility, according to exemplary embodiments. In an embodiment, FIGS. 3A, 3B, and 3C show an illustration including a 3D digital twin environment 302 rendered by the rendering engine 224 of the inspection processing system 102, described in FIG. 2. The 3D digital twin environment 302 may correspond to an application deployed for determining optimized number and positions of inspection locations corresponding to one or more physical piping arrangements in a facility, such as a refinery. The application may correspond to one of an application software, a mobile app, or a web app. The application program may be a computer program designed to carry out a specific task other than one relating to the operation of the computer itself, typically to be used by end-users. The mobile application or app may be a computer program or software application designed to run on a mobile device, such as a phone, a tablet, or a smart watch. The web application may be an application software that is accessed using a web browser and delivered on the World Wide Web to the client device 110 with an active network connection.

The 3D digital twin environment 302 may be rendered at a workspace area of a user interface (UI) 304 of a display device 306. In an embodiment, the display device 306 may be associated with the inspection processing system 102. In accordance with another embodiment, the display device 306 may be associated with the client device 110. The UI 304 may include various graphical components, such as a menu 308 and a UI toolbox 310. The menu 308 and the UI toolbox 310 may allow the user 112 (associated with the client device 110) to choose from a specified list of options (in the case of the menu 308) or to click buttons, widgets, checkboxes, progress bars, and/or navigation buttons (in the case of the UI toolbox 310) to affect some change to the application and the 3D digital twin environment 302. Examples of the specified list of options in the menu 308 may correspond to file 308a, edit 308b, view 308c, and the like. Examples of the buttons of the UI toolbox 310 may correspond to controls 310a, scripts 310b, a debugger 310c, and the like. A first 3D virtual model 312 of a first piping arrangement 314 may be displayed in the 3D digital twin environment 302 rendered at a workspace area of the UI 304.

In accordance with a first example as illustrated in the exemplary scenario 300A of FIG. 3A, based on established piping inspection standards (that correspond to the plurality of guidelines or predefined rules, as described in FIGS. 1 and 2), the determination engine 216 may calculate or conclude that three inspection locations, such as (IP1, L1), (IP2, L2), and (IP3, L3), are required at approximately 80-foot increments on different straight sections of the first piping arrangement 314 in the first 3D virtual model 312. However, the same first piping arrangement 314 may also include a low point (LP) in the first 3D virtual model 312. The user 112 (or inspector) may provide a user preference for determining that an inspection location (IP4, L4) should be placed at the identified low point (LP) even though the inspection location (IP4, LA) is not required as per the piping inspection standards and may be closer or farther than the 80-foot guideline recommendation. Therefore, the user 112 may decide to move one of the three points to the low point (LP) or based on a discretion, add an additional inspection location, i.e., the inspection location (IP4, L4), to assure inspection of the low point (LP).

In accordance with a second example as illustrated in the exemplary scenario 300B of FIG. 3B, the established piping inspection standards (that correspond to the plurality of guidelines or predefined rules, as described in FIGS. 1 and 2) may state that inspection points are required at 80-foot increments at low points, for example at inspection locations (IP5, L5), (IP6, L6), (IP7, L7), and (IP8, L8) and at every 4th elbow, for example at inspection location (IP9, L9). Placing the inspection locations strictly following the established piping inspection standards independently may locate more points than are necessary. For example, not shifting points along a straight pipe to account for low spots or points. The user 112 may recognize that such guidelines or predefined rules are not specifically mandated and thus, place fewer points more optimally. This may result in a reduced number of inspection locations, i.e., the inspection locations (IP5, L5), (IP6, L6), (IP8, L8), and (IP9, L9) only.

In accordance with a third example as illustrated in the exemplary scenario 300C of FIG. 3C, the determination engine 216 from the inspection engine 214 may perform proximity consideration applied to the positioning of inspection locations as related to adjacent piping systems, such as a second piping arrangement 316. Once new inspection locations are placed on all the piping systems, such as the first piping arrangement 314 and the second piping arrangement 316 in the 3D digital twin environment 302 and prior to finalizing the inspection locations, there is an opportunity to consider proximity between adjacent assets, such as the first pipe from the first piping arrangement 314 and the second pipe from the second piping arrangement 316 that require inspection.

In such exemplary scenario, the adjacent piping systems, such as the second piping arrangement 316, may require inspection. Based on positioning of the inspection locations, such as market points MP1, MP2, . . . , MP7, as close as possible to another point on the adjacent piping systems, such as the second piping arrangement 316, more rapid and efficient inspection may be facilitated.

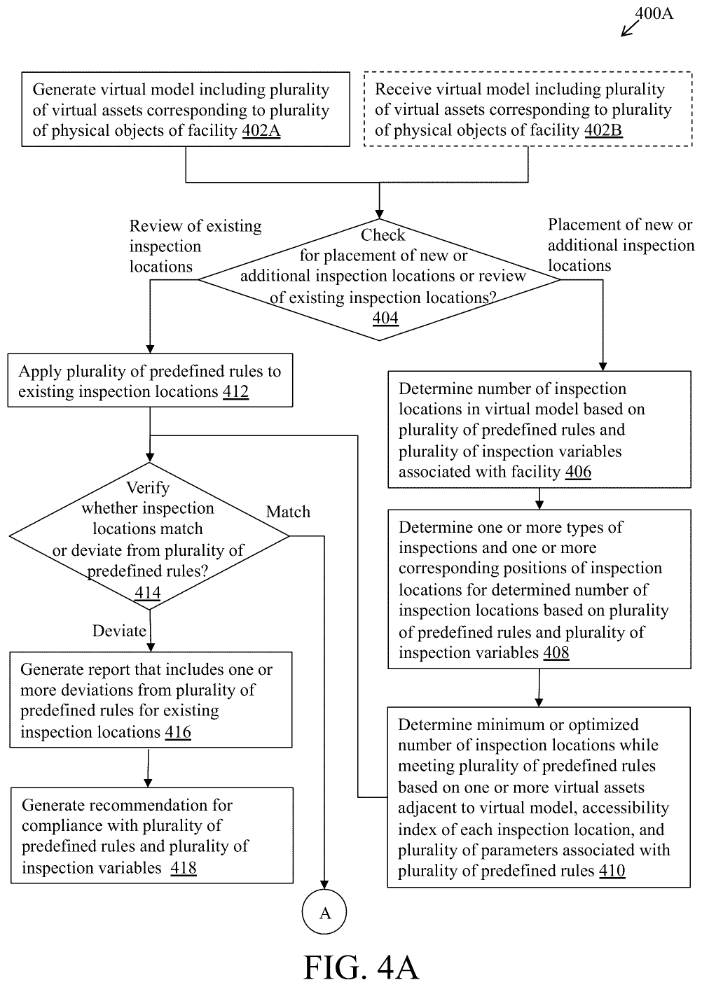

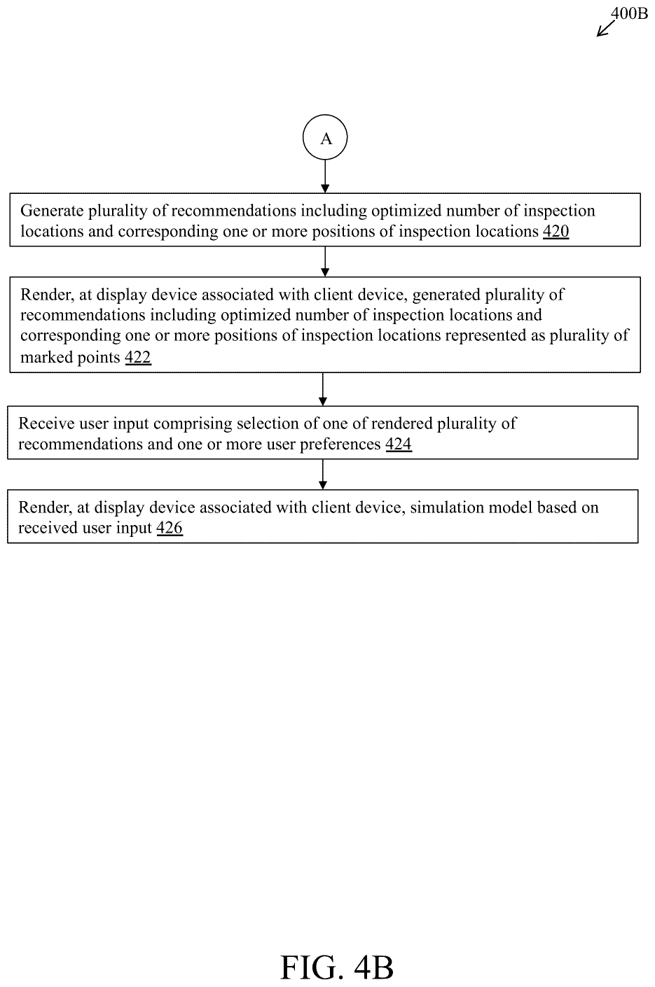

FIGS. 4A and 4B show flowcharts 400A and 400B collectively depicting a method that includes operational steps for determining optimized number and positions of inspection locations corresponding to physical objects in a facility, according to exemplary embodiments. FIGS. 4A and 4B are described in conjunction with FIGS. 1 to 3C.

At 402A, a virtual model, including a plurality of virtual assets corresponding to the one or more physical objects 106 of the facility 104, may be generated. In an embodiment, the 3D modelling engine 210 may execute operations to generate the virtual model including the plurality of virtual assets corresponding to the one or more physical objects 106 of the facility 104.

In an embodiment, the virtual model may correspond to a digital twin, which is a digitized version of the physical objects 106 replicating the condition of the one or more physical objects 106 as a whole as well as individual components of the one or more physical objects 106 as indicated by the sensors 108. Said differently, the digital twin of the physical objects 106 accurately reflects the mechanical condition of the one or more physical objects 106 and whether particular parts of the one or more physical objects 106 will need to be replaced in the near future.

In an embodiment, the 3D modelling engine 210 may include code and routines that are operable, when executed by the processor 202, generate model data that describes the virtual model corresponding to the one or more physical objects 106. The model data includes data necessary to cause the 3D modelling engine 210 to generate a virtualized version of the physical objects 106. In an embodiment, the virtual model may be generated based on data received from the sensors 108 and the plurality of guidelines or predefined rules. The virtual model may be further generated based on a plurality of inspection variables received based on the plurality of guidelines or predefined rules. The plurality of inspection variables may be received individually as data values via a user interface or collectively as a data table. The virtual model may be further generated based on additional inspection variables corresponding to one or more attributes of the one or more physical objects 106.

In accordance with various embodiments, the plurality of guidelines or predefined rules may be received from one or more components of the network environment 100, such as the client device 110, the operating entity 114, and/or the external agency/regulatory agency 116, via the network 118 and the NIC 206. The plurality of guidelines or predefined rules may correspond to standard operating procedures that may be established based on an operational requirement of the facility 104 and managed by one of the external agencies/regulatory agencies 116.

In an embodiment, the plurality of inspection variables may be received for the virtual model based on the plurality of guidelines or predefined rules. In accordance with another embodiment, the plurality of guidelines or predefined rules may be established, and plurality of inspection variables may be received individually as data values via a user interface or collectively as a data table into the data and application repository 228. For example, the plurality of guidelines or predefined rules may be entered as the inspection variables in, for example, V-Suite® software, by the user 112 at the inspection processing system 102 or the client device 110.

In an embodiment, the plurality of guidelines or predefined rules may be used for an automated placement of at least one of new inspection locations or additional inspection locations in the virtual model. In accordance with another embodiment, the plurality of guidelines or predefined rules may be used for a review and the optimization of new or existing inspection locations in the virtual model.

Examples of the new, additional, or existing inspection locations, may include, for example, thickness monitoring locations (TMLs), corrosion monitoring locations (CMLs) or Fugitive Emission type inspection points. However, it should be noted that the above examples should not be construed to be limiting, and guidelines or predefined rules for other type of fixed points may also be established in the plurality of guidelines or predefined rules and the plurality of inspection variables to facilitate point review, optimization, reduction, addition and/or placement of the inspection locations.

Non-limiting examples of the plurality of guidelines or predefined rules and variables may include system or application program interface (API) classification, inspection location density by system classification (and component type), damage mechanisms, inspection circuit or loop category, inspection location naming convention, integrity operating window, injection point rules, dead leg(s), accessibility, and other pre-defined or custom variables, conflicts, and exceptions. Additional variables or asset attributes, for example, asset elevation (absolute and relative) may also be included.

At 402B, in accordance with an alternative embodiment, the 3D modelling engine 210 may execute operations to receive the virtual model including the plurality of virtual assets corresponding to the one or more physical objects 106 of the facility 104. The virtual model may be received by the 3D modelling engine 210 from an external device or modelling server. In such an embodiment, the external device or modelling server may be communicatively coupled with the inspection processing system 102, via the network 118.

At 404, it may be checked whether placement of at least one of new inspection locations or additional inspection locations are to be determined or review of existing inspection locations is to be performed. In an embodiment wherein at least one of new inspection locations or additional inspection locations are to be determined, the control passes to step 406. In accordance with another embodiment wherein the existing inspection locations are to be reviewed, the control passes to step 412.

At 406, a number of inspection locations may be determined in the virtual model based on the plurality of predefined rules and the plurality of inspection variables associated with the one or more physical objects 106. In an embodiment, the determination engine 216 may execute operations to determine the number of inspection locations in the virtual model.

In an embodiment, the number of inspection locations may be determined based on an application of the plurality of guidelines or predefined rules to a plurality of inspection circuits or loops. When determining the number of inspection locations for an exemplary piping system, inspection loops may be determined. The inspection loops may refer to areas of the exemplary piping system that are physically separated by valves, flanges, or other mechanical barriers.

The determination engine 216 may determine the number of inspection locations based on the complexity and criticality of the exemplary piping system. For example, a highly critical system with a complex design may require more inspection locations than a simple system with a lower criticality level. The inspection locations may be strategically placed to ensure that all critical areas of the exemplary piping system are inspected regularly. This includes areas where corrosion or other forms of degradation are likely to occur, as well as areas that are prone to stress or other forms of mechanical damage.

The determination engine 216 may further determine the number of inspection locations based on a type of inspection method being used. For example, visual inspections may require more frequent inspection locations than other methods, such as ultrasonic testing. Thus, the determination engine 216 may determine the number of inspection locations for the exemplary piping system based on a specific design of the exemplary piping system, the type of inspection method being used, and the level of criticality of the exemplary piping system. By strategically placing the inspection locations along the inspection loops or circuits, the exemplary piping system may be inspected regularly to ensure its safety, reliability, and compliance with industry standards.

At 408, for the determined number of inspection locations, one or more type of inspections and one or more corresponding positions of the inspection locations may be determined based on the plurality of predefined rules and the plurality of inspection variables. In an embodiment, the determination engine 216 may be further configured to determine one or more type of inspections and one or more corresponding positions of the inspection locations for the determined number of inspection locations based on the plurality of predefined rules and the plurality of inspection variables.

The determination engine 216 may apply the plurality of predefined rules to automate or semi-automate the naming and physical placement of inspection locations in the 3D virtual model. For example, the determination engine 216 may identify physical locations for TML or CML for piping and equipment. In another example, the determination engine 216 may identify physical locations for routine inspections of process equipment with gas detectors to detect fugitive emissions. In yet another example, the determination engine 216 may identify points of interest in a process facility model, for example, Refinery, Chemical Plant, and the like.

In an embodiment, the number of inspection locations, the one or more types of inspections and the one or more corresponding positions of the inspection locations may be determined based on an application of the plurality of guidelines or predefined rules to the plurality of inspection circuits or loops. The determination of the number of inspection locations, the one or more type of inspections, and the one or more corresponding positions for an exemplary piping system is a complex process that requires careful consideration of industry guidelines or predefined rules, the specific design of the system, and the criticality of the application. By applying such guidelines or predefined rules to the inspection loops or circuits of the exemplary piping system, an optimal inspection program may be developed to ensure the safety and reliability of the exemplary piping system.

In accordance with an exemplary scenario, a piping system, critical to the operation of a chemical plant, may include multiple inspection loops. Such inspection loops may be physically separated by valves and other mechanical barriers. To ensure the safety and reliability of the piping system, an optimal number of inspection locations, types of inspections, and corresponding positions of the inspection locations may be required to be properly determined. Accordingly, a variety of industry guidelines or predefined rules may be applied, including API 570 (Piping Inspection Code), ASME B31.3 (Process Piping), and NACE SP0102 (Control of Internal Corrosion in Steel Pipelines and Piping Systems). Such guidelines or predefined rules may provide detailed criteria for the inspection and maintenance of the piping system, including recommended number and positioning of inspection locations for each inspection loop or circuit.

Based on such guidelines or predefined rules, the number of inspection locations for each loop or circuit may be determined based on the size, complexity, and criticality of the piping system. For example, a loop with a large diameter or a complex design may require more inspection locations than a simpler loop with a smaller diameter. The types of inspections to be performed at each inspection location may also be determined based on the guidelines or predefined rules. Such types of inspections may include, but are not limited to, visual inspections, ultrasonic testing, radiography, or other non-destructive testing methods.

Finally, the corresponding positions of the inspection locations may be determined based on the guidelines or predefined rules and the specific design of the piping system. Such positions may correspond to critical areas, such as areas subjected to high stress, potential corrosion or erosion, and other factors that may affect the integrity of the piping system.

At 410, based on one or more virtual assets adjacent to the virtual model, an accessibility index of each inspection location, and a plurality of parameters associated with the plurality of guidelines or predefined rules, a minimum or optimized number of inspection locations and the corresponding one or more positions of the inspection locations may be determined. In an embodiment, the recommendation engine 218 may execute operations to determine a minimum or optimized number of inspection locations and the corresponding one or more positions of the inspection locations based on one or more virtual assets adjacent to the virtual model, an accessibility index of each inspection location, and a plurality of parameters associated with the plurality of guidelines or predefined rules. Based on adjacency and accessibility, the optimization of placement of inspection locations may help to reduce the overall number of inspection locations required while still providing comprehensive coverage of the piping system. By carefully considering such factors, along with other critical factors, an optimal inspection program may be developed to ensure the safety and reliability of the piping system.

Adjacency may correspond to closeness of inspection locations with respect to each other. When determining the placement of inspection locations, adjacency of the inspection locations is a significant criterion. Inspection locations that are close to one another may reduce the overall number of inspection locations required while still providing comprehensive coverage of the piping system. This may result in cost savings and reduced downtime for the piping system.

Accessibility may correspond to case of approach or reach of an inspection location. It is important to ensure that the inspection locations are easily accessible for inspection personnel. Locations that are difficult to access, such as those located in tight spaces or behind obstructions, may result in increased inspection time and cost. In some cases, inaccessible inspection locations may even be impossible to inspect without disassembling the piping system.

Therefore, to optimize the placement of inspection locations based on adjacency and accessibility, it may be helpful to create the 3D virtual model, that also includes a map or diagram of the inspection loops or circuits, as illustrated in the exemplary scenario 300C of FIG. 3C. Accordingly, various areas may be identified where multiple inspection locations may be clustered together while still providing comprehensive coverage of the piping system. The accessibility of each inspection location may also be considered, and adjustments may be made to the placement of locations to ensure that they are easily accessible for inspection personnel.

It should be noted that while adjacency and accessibility are important factors to consider when determining the placement of inspection locations, they should not be construed to be limiting and the only factors considered. Without any deviation from the scope of the disclosure, the criticality of the piping system, the type of inspection method being used, and other factors may also be considered to ensure the optimal inspection program is developed for the piping system.

The optimization engine 220 may execute operations to determine a minimum number of inspection locations to consider subsequent physical, visual, or other required inspections based on various inspection variables, such as inspection routing, one or more virtual assets adjacent to the virtual model, and an accessibility index of each inspection location. The optimization engine 220 may execute operations to determine the minimum or optimized number of inspection locations while meeting the plurality of predefined rules. The minimum or optimized number of inspection locations facilitates more rapid inspection by geo-locating inspection points ‘nearby’ other inspection points, thereby making more accessible, or otherwise ‘easier’ inspection locations for documentation. Consequently, more inspections may be completed in less time leading to an improved facility reliability. Control passes to step 414.

At 412, the plurality of predefined rules may be applied to the existing inspection locations. In an embodiment, the verification engine 222 may execute operations to apply the plurality of predefined rules to the existing inspection locations. The plurality of predefined rules may be used for a review and the optimization of new or existing inspection locations for the one or more virtual assets. The determination engine 216 may apply the plurality of predefined rules and inspection variables to already placed inspection locations in the 3D virtual model. Accordingly, the user 112 may be presented with compliance with or divergence from the plurality of predefined rules and the inspection variables.

At 414, it may be verified whether existing inspection locations match or deviate from the plurality of predefined rules. In an embodiment, the verification engine 222 may execute operations to verify whether existing inspection locations match or deviate from the plurality of predefined rules. In one case, when the verification engine 222 verifies that the existing inspection locations deviate from the plurality of predefined rules, the control passes to step 416. In other case, when the verification engine 222 verifies that the existing inspection locations match with the plurality of predefined rules, the control passes to step 420.

At 416, a report may be generated that includes one or more deviations from the plurality of predefined rules for existing inspection locations. In an embodiment, the reporting engine 226 may execute operations to generate a report that includes one or more deviations from the plurality of predefined rules for existing inspection locations. The generated report may be in a relevant format that, may itself be configurable by the user 112 for the user 112 to decide one or multiple times on an ongoing basis.

The one or more deviations may correspond to a positional deviation of the inspection locations, for example, an angular (or rotational) deviation, a missing inspection location, a mix-up of names of inspection locations (i.e., a different component being placed), different polarities (i.e., the polarity of the inspection location different from the polarity described in the plurality of guidelines or predefined rules), and the like. The one or more deviations may correspond to functional or operational deviation, for example, abnormal temperature, pressure, vibration, corresponding to each inspection location as described in the plurality of predefined rules.

At 418, a plurality of recommendations may be generated for a compliance with the plurality of predefined rules and the plurality of inspection variables. In an embodiment, the recommendation engine 218 may be further configured to generate a recommendation for a compliance with the plurality of predefined rules and the plurality of inspection variables. The generated recommendation may be rendered and displayed at the client device 110 for the user 112 to ensure that the planning and execution physical inspection is efficient and non-redundant.

At 420, a plurality of recommendations including the optimized number of inspection locations and the corresponding one or more positions of the inspection locations may be generated. In an embodiment, recommendation engine 218 may execute operations to generate the plurality of recommendations including the optimized number of inspection locations and the corresponding one or more positions of the inspection locations.

At 422, a plurality of recommendations including the optimized number of inspection locations and the corresponding one or more positions of the inspection locations represented as a plurality of marked points, may be rendered at a display device associated with the client device 110. In an embodiment, the rendering engine 224 may execute operations to render the generated plurality of recommendations including the optimized number of inspection locations and the corresponding one or more positions of the inspection locations represented as a plurality of marked points.

The rendering engine 224 may include a GPU (not shown), the functionality of which may be utilized by a software application stored in the data and application repository 228. For example, the software application may be a GUI application, an operating system, a portable mapping application, a video game application, a computer-aided design program for engineering or artistic applications, or another type of software application that may utilize the GPU. In an embodiment, the software application may represent a virtual reality (VR) application or an augmented reality (AR) application. The software application may send data representing a viewpoint of the user 112, determined using one or more of external cameras, accelerometers, gyroscopes, or the like, to GPU via a graphics API and a GPU driver. The viewpoint data may be used by the GPU of the rendering engine 224 to determine one or more camera positions, such as a single camera position for a single image, or multiple camera positions for a left-eye image and a right-eye image. The software application may include one or more drawing instructions that instruct the GPU of the rendering engine 224 to render the plurality of marked points in the GUI and a graphics scene with annotations.

In an exemplary scenario, an effort may be calculated to identify and position new inspection marked points in a 3D digital twin, i.e., a 3D virtual model. The following table, Table 1, outlines the effort required to identify and position the inspection marked points on new implementations of 3D digital twin where there is no inspection program in place.

TABLE 1

| Effort to Place | | | Average Hours |
|---|---|---|---|
| New Inspection | | Average | per Asset/ |
| Locations in the | Average No. | Points per | Physical |
| 3D Model | of Points | Hour | Object |
| Equipment: Air Cooler | 36.4 | 17.3 | 2.1 |
| Equipment: Drum | 143.9 | 26.0 | 5.5 |
| (PSI Vessels & Spheres) | | | |
| Equipment: Fired Heater | 675.3 | 21.7 | 31.2 |
| Equipment: Shell & Tube | 75.7 | 26.0 | 2.9 |
| Exchanger | | | |
| Equipment: Tower | 68.4 | 13.9 | 4.9 |
| Piping Systems/Loops | N/A | 25.0 | N/A |

In one case, utilizing the previously mentioned quantities and efforts in Table 1, the determination engine 216 may execute operations to estimate approximately how long it would take to place inspection locations in a 3D model for a variety of facility sizes or types. Various estimates, as tabulated in Table 2, correspond to the effort to locate and position the inspection marked points in the 3D virtual Model based on a manual placement metrics above for a relatively Small facility having, for example, less than 40,000 Inspection Locations.

TABLE 2

| Example Small | | | |
|---|---|---|---|
| Facility-New | | | |
| Inspection Location | Pieces of | Inspection | Estimated |
| Placement Effort | Equipment | Locations | Hours |
| Equipment: Air Cooler | 10 | 364 | 21 |
| Equipment: Drum | 175 | 25,183 | 969 |
| (PSI Vessels & Spheres) | | | |
| Equipment: Fired Heater | 6 | 4,052 | 187 |
| Equipment: Shell & Tube | 86 | 6,509 | 250 |
| Exchanger | | | |
| Equipment: Tower | 8 | 547 | 39 |
| Piping Systems/Loops | N/A | 2,303 | 92 |
| Total | 285 | 38,958 | 1,559 |

In another case, if the placement of inspection marked points is scaled up to a Medium to Large facility, the following Table 3 outlines the estimated manual effort to place inspection marked points:

TABLE 3

| Example Medium to | | | |
|---|---|---|---|
| Large Facility- | | | |
| New Inspection | Pieces of | Inspection | Estimated |
| Location Placement | Equipment | Locations | Hours |
| Equipment: Air Cooler | 40 | 1456 | 84 |
| Equipment: Drum | 300 | 43,171 | 1661 |
| (PSI Vessels & Spheres) | | | |
| Equipment: Fired Heater | 20 | 13,507 | 623 |
| Equipment: Shell & Tube | 300 | 22,706 | 874 |
| Exchanger | | | |
| Equipment: Tower | 50 | 3419 | 247 |
| Piping Systems/Loops | N/A | 115,742 | 4630 |
| Total | 710 | 200,000 | 8,119 |

At 424, a user input including a selection of one of the rendered plurality of recommendations and one or more user preferences may be received. In an embodiment, the processor 202 may execute operations to receive the user input including the selection of one of the rendered plurality of recommendations and one or more user preferences. The user input may be received from the user 112 associated with the client device 110.

At 426, a simulation model may be rendered based on the received user input. In an embodiment, the rendering engine 224 in conjunction with the 3D modelling engine 210 and the simulation engine 212 may execute operations to render the simulation model at the display device associated with the client device 110 based on the received user input.

In accordance with an embodiment, the simulation model may be generated by the simulation engine 212, in conjunction with the 3D modelling engine 210, based on a user input provided by the user 112 at the client device 110. The user input may include a selection of one of the plurality of recommendations and one or more user preferences provided by the user 112. Such simulation model may accurately predict when the one or more physical objects 106 will be in a state to receive proactive maintenance before a breakdown event occurs, for example, a failed component.

In an embodiment, the simulation engine 212 may implement AI simulation using scenario data and asset data of other physical objects in the facility 104. The asset data of other physical objects may be retrieved from the sensors 108 and the data and application repository 228. The scenario data may correspond to information including risky scenarios that could not be tested in the real world, for example, a damaged physical object. The asset data of other physical objects may correspond to physical attributes, design specifications, and/or standard operating procedures of the other physical objects.

In accordance with an embodiment, the simulation engine 212, in conjunction with the 3D modelling engine 210, may model a virtual world for the one or more physical objects 106 located in the facility 104 and engage in perception, path planning, and autonomous driving as it would operate in the real world. Software-in-the-loop and AI executing in the simulation engine 212 may control other physical objects that a simulated physical object from the one or more physical objects 106 might encounter. In an embodiment, the simulation engine 212 may execute operations to calculate the inspection costs for every recommended candidate solution.

It should be noted that the method, sequence and/or algorithm described in connection with the embodiments disclosed herein may be embodied directly in firmware, hardware, in a software module executed by the processor 202, the plurality of individual processing engines (i.e., the 3D modelling engine 210, the simulation engine 212, and the inspection engine 214 (including the determination engine 216, the recommendation engine 218, the optimization engine 220, the verification engine 222, the rendering engine 224, and the reporting engine 226), or in a combination thereof. A software module may reside in the memory 204, such as RAM memory, flash memory, ROM memory, EPROM memory, EEPROM memory, registers, hard disk, physical and/or virtual disk, a removable disk, a CD-ROM, virtualized system, or device such as a virtual servers or container, or any other form of storage medium known in the art. An exemplary storage medium, such as the data and application repository 228, is communicatively coupled to the processor 202 (including logic/code executing in the processor) and the plurality of individual processing engines such that the processor 202 and the plurality of individual processing engines can read information from, and write information to, the storage medium. In the alternative, the storage medium may be integral to the processor 202 and/or the plurality of individual processing engines.

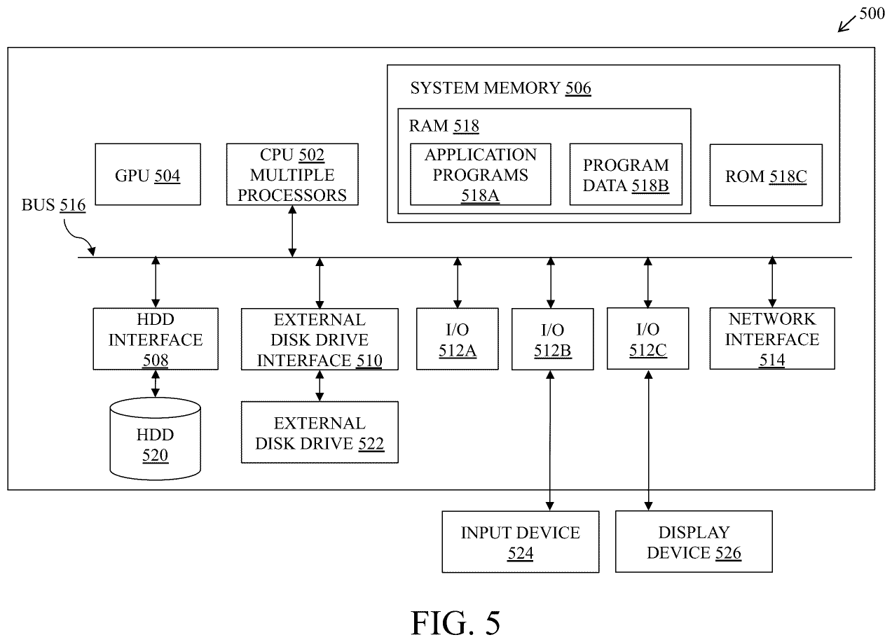

FIG. 5 shows an exemplary hardware configuration of computer 500 that may be used to implement components of a system for determining optimized number and positions of inspection locations corresponding to physical objects 106 in a facility, according to exemplary embodiments.

The computer 500 shown in FIG. 5 includes a CPU 502, a GPU 504, a system memory 506, a hard disk drive (HDD) interface 508, an external disk drive interface 510, input/output (I/O) interfaces 512A, 512B, 512C, and a network interface 514. These elements of the computer are coupled to each other via a system bus 516.

The CPU 502 may perform arithmetic, logic and/or control operations by accessing the system memory 506. The CPU 502 may implement the processors of the exemplary devices and/or system described above.

The GPU 504 may perform operations for processing graphic or AI tasks. In case the computer 500 is used for implementing exemplary central processing device, GPU 504 may be GPU 504 of the exemplary central processing device as described above. The computer 500 does not necessarily include GPU 504, for example, in case the computer 500 is used for implementing a device other than central processing device.

The system memory 506 may store information and/or instructions for use in combination with the CPU 502. The system memory 506 may include volatile and non-volatile memory, such as random-access memory (RAM) 518 and read only memory (ROM) 518C. A basic input/output system (BIOS) containing the basic routines that helps to transfer information between elements in the computer 500, such as during start-up, may be stored in ROM 518C. The system bus 516 may be any of several type of bus structures including a memory bus or memory controller, a peripheral bus, and a local bus using any of a variety of bus architectures.

The computer may include the network interface 514 for communicating with other computers and/or devices via a network.

Further, the computer may include HDD 520 for reading from and writing to a hard disk (not shown), and external disk drive 522 for reading from or writing to a removable disk (not shown). The removable disk may be a magnetic disk for a magnetic disk drive or an optical disk such as a CD ROM for an optical disk drive. The HDD 520 and external disk drive 522 are connected to the system bus 516 by HDD interface 508 and external disk drive interface 510 respectively. The drives and their associated non-transitory computer-readable media provide non-volatile storage of computer-readable instructions, data structures, program modules and other data for the general-purpose computer. The relevant data may be organized in a database, for example a relational or object database.

Although the exemplary environment described herein employs a hard disk (not shown) and an external disk (not shown), it should be appreciated by those skilled in the art that other type of computer readable media which can store data that is accessible by a computer, such as magnetic cassettes, flash memory cards, digital video disks, random access memories, read only memories, and the like, may also be used in the exemplary operating environment.

A number of program modules may be stored on the hard disk, external disk, ROM 518C, or RAM 518, including an operating system (not shown), one or more application programs 518A, other program modules (not shown), and program data 518B. The application programs may include at least a part of the functionality as described above.

The computer 500 may be connected to an input device 524, such as mouse and/or keyboard and a display device 526, such as liquid crystal display, via corresponding I/O interfaces 512A to 512C and the system bus 516. In addition to an implementation using a computer 500 as shown in FIG. 5, a part or all the functionality of the exemplary embodiments described herein may be implemented as one or more hardware circuits. Examples of such hardware circuits may include, for example, Large Scale Integration (LSI), RISC, ASIC, and FPGA.

Various embodiments of the disclosure include the inspection processing system 102 that may be configured for determining optimized number and positions of inspection locations at the one or more physical objects 106 in the facility 104. The inspection processing system 102 includes a memory, such as the memory 204 for storing instructions. The inspection processing system 102 further includes a processor (such as one or more of the processor 202 or the plurality of individual processing engines, such as the 3D modelling engine 210, the simulation engine 212, and the inspection engine 214, hosted on the inspection processing system 102) configured to execute the instructions, and based on the instructions, the processor, such as the determination engine 216, may be further configured to determine a number of inspection locations in the virtual model, such as the first 3D virtual model 312 and/or a second 3D virtual model 318, based on a plurality of guidelines or predefined rules and a plurality of inspection variables associated with the one or more physical objects 106 in the facility 104. In an embodiment, the virtual model corresponding to the one or more physical objects 106 may be generated based on the 3D modeling of the facility 104.

In an embodiment, the plurality of guidelines or predefined rules may correspond to standard operating procedures that are established based on an operational requirements of the facility and managed by one of an external agency or a regulatory agency.

In an embodiment, the plurality of guidelines or predefined rules may enable placement of at least one of new inspection locations or additional inspection locations in the virtual model.

In an embodiment, the plurality of guidelines or predefined rules may enable a review and optimization of new or existing inspection locations in the virtual model.

For the determined number of inspection locations, the processor, such as the determination engine 216, may be further configured to determine one or more type of inspections and one or more corresponding positions of the inspection locations based on the plurality of guidelines or predefined rules and the plurality of inspection variables. The number of inspection locations, the one or more type of inspections and the one or more corresponding positions of the inspection locations may be determined based on an application of the plurality of guidelines or predefined rules to a plurality of inspection circuits or loops. The inspection locations may correspond to one of physical locations for Thickness Monitoring Locations (TML), Corrosion Monitoring Locations (CML) for piping and equipment, routine inspections of process equipment with gas detectors, or other points of interest in the facility.

Based on one or more virtual assets adjacent to the virtual model, an accessibility index of each inspection location, and a plurality of parameters associated with the plurality of guidelines or predefined rules, the processor, such as the recommendation engine 218, may execute operations to generate a plurality of recommendations including an optimized number of inspection locations and the corresponding one or more positions of the inspection locations. The processor, such as the rendering engine 224 in conjunction with the optimization engine 220, may execute operations to render the generated plurality of recommendations including the optimized number of inspection locations and the corresponding one or more positions of the inspection locations represented as a plurality of marked points. A physical inspection of the one or more physical objects 106 may be planned and executed based on the plurality of marked points.

In an embodiment, the processor, such as the processor 202 and the determination engine 216, may be further configured to receive the virtual model including the plurality of virtual assets corresponding to the one or more physical objects 106 of the facility 104.

In an embodiment, the processor, such as the 3D modelling engine 210, may be further configured to generate the virtual model including the plurality of virtual assets corresponding to the one or more physical objects 106 in the facility 104.

In an embodiment, the processor, such as the processor 202, may be further configured to receive the plurality of inspection variables for the virtual model based on the plurality of guidelines or predefined rules. The plurality of inspection variables may be received individually as data values via a user interface or collectively as a data table.

In an embodiment, the processor, such as the determination engine 216, may be further configured to receive additional inspection variables corresponding to one or more attributes of the one or more physical objects 106. Accessibility indices of the inspection locations may be determined based on the plurality of guidelines or predefined rules, the plurality of inspection variables, and the additional inspection variables exceed a threshold value.

In an embodiment, the processor, such as the verification engine 222 may be further configured to verify whether at least one of the inspection locations or existing inspection locations match or deviate from the plurality of guidelines or predefined rules. The reporting engine 226 may generate a report that includes one or more deviations from the plurality of guidelines or predefined rules for the at least one of the inspection locations or the existing inspection locations. The recommendation engine 218 may generate a recommendation for a compliance with the plurality of guidelines or predefined rules and the plurality of inspection variables.

In an embodiment, the processor 202 may be further configured to receive a user input including a selection of one of the rendered plurality of recommendations and one or more user preferences. The rendering engine 224 in conjunction with the simulation engine 212 may execute operations to render, at a display device associated with the client device 110, a simulation model based on the received user input.

Various embodiments of the disclosure may provide a computer readable medium, such as the non-transitory second computer readable medium, having stored thereon, computer implemented instruction that when executed by a processor, such as the processor 702 or the plurality of individual processing engines, causes the inspection processing system 102 to execute operations for determining optimized number and positions of inspection locations at the one or more physical objects 106 in the facility 104. In an embodiment, the processor causes the inspection processing system 102 to execute operations to determine a number of inspection locations in the virtual model, such as the first 3D virtual model 312 and/or the second 3D virtual model 318, based on the plurality of guidelines or predefined rules and the plurality of inspection variables associated with the one or more physical objects 106 in the facility 104. In an embodiment, the virtual model corresponding to the one or more physical objects 106 may be generated based on the 3D modeling of the facility 104.

For the determined number of inspection locations, the processor further causes the inspection processing system 102 to execute operations to determine one or more type of inspections and one or more corresponding positions of the inspection locations based on the plurality of guidelines or predefined rules and the plurality of inspection variables. The number of inspection locations, the one or more type of inspections and the one or more corresponding positions of the inspection locations may be determined based on an application of the plurality of guidelines or predefined rules to a plurality of inspection circuits or loops.

Based on one or more virtual assets adjacent to the virtual model, an accessibility index of each inspection location, and a plurality of parameters associated with the plurality of guidelines or predefined rules, the processor further causes the inspection processing system 102 to generate a plurality of recommendations including an optimized number of inspection locations and the corresponding one or more positions of the inspection locations.

The processor further causes the inspection processing system 102 to render the generated plurality of recommendations including the optimized number of inspection locations and the corresponding one or more positions of the inspection locations represented as a plurality of marked points. A physical inspection of the one or more physical objects 106 may be planned and executed based on the plurality of marked points.

The proposed system and method for optimizing inspection locations in a facility provides various advantages. Over a time, physical objects may experience defects (such as mechanical defects, electrical defects, a routine wear-and-tear, and the like) that may adversely impact the operation, performance, and life span of the physical objects. Alternatively, in some instances, spontaneous failures of one or more components or systems of the physical objects may occur which may be unrelated to wear or maintenance conditions but may instead be attributable to an undetected defect or an unknown stressor. Regardless of whether the defect is due to gradual process or a sudden occurrence, the health of the physical objects depends on identifying and addressing such defects at defined inspection locations in a timely and effective manner.

In existing systems and methods, placement, verification, and review of the inspection locations is performed visually and manually to assure that quantity and location of the inspection locations meets or exceeds the standards or guidelines or predefined rules. As the placement is not optimized, therefore, assurance of compliance with standard(s) is not offered and inefficiencies and redundancy are caused in physical inspection planning and execution. Strictly following the guidelines or predefined rules or standards may place the inspection locations in a manner that is not desirable. In an example, the inspection locations may be staggered in a pipe way. In another example, the inspection locations may be placed in areas in the facility that may or may not consider case of access. In yet another example, the inspection locations may be placed in locations that are not readily accessible without the use of ladders, scaffold, or some other extra-ordinary method to access the inspection locations visually or physically. In some existing systems and methods, recommended quantity of inspection locations versus already placed quantity of locations are analysed or reported. However, such existing systems and methods are deficient of establishing rules (or guidelines or predefined rules), providing the inspection locations in a 3D virtual environment, and not recommended or automatically placing inspection locations using automated macros or other means.

In accordance with the proposed system and method, based on the plurality of guidelines or predefined rules and subsequent inspection variables applied in the 3D digital twin environment, the number and placement of inspection locations may be automatically calculated and recommended thereafter. The placement may be further streamlined and optimized based on additional variables, such as adjacency and other such factors (such as asset attributes), to facilitate a rapid inspection by geo-locating inspection locations ‘nearby’ or directly adjacent to other inspection locations. What can be achieved is increased accessibility without reducing the inspection quality or reliability of the required inspection.

Accordingly, such placement of the inspection locations is more accessible both visually and physically from grade, platforms, or other assets in the facility, requiring minimized scaffold requirements, assuring inspection quality or reliability of required inspection. Further, such placement of the inspection locations is otherwise ‘easier’ to document. Such recommended inspection locations may not require any change, effectively reduce placement effort to near zero, while remaining in compliance with the plurality of guidelines or predefined rules, and streamlining physical inspection activities. Consequently, more inspections may be completed in less time, thereby improving facility reliability, reducing project delivery schedules, saving several man-years in total effort and associated costs to identify and place the inspection locations, controlling the sell price of assets, and enhancing margins of the assets.

Intended commercial applications may include, for example, reduction of project costs and improved schedules. If applied by 3D virtual model users, the 3D digital twin/virtual model projects for inspection may immediately leverage the effort-hours saved when placing the inspection marked points on projects.

Those of skill in the art will appreciate that the various illustrative logical blocks, modules, processing engines, circuits, algorithms, and/or steps described in connection with the embodiments disclosed herein may be implemented as electronic hardware, computer software, firmware, or combinations thereof. To clearly illustrate this interchangeability of hardware and software, various illustrative components, blocks, modules, engines, circuits, and steps have been described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

It should be noted that all or parts of hardware components of the system disclosed herein may readily be provided in a system-on-a-chip (SoC), including a central processing unit (CPU) package. In an embodiment, the SoC may correspond to an integrated circuit (IC) that integrates components of a computer or other electronic system into a single chip. The SoC may contain digital, analogue, mixed-signal, and radio frequency functions, all of which may be provided on a single chip substrate. Other embodiments may include a multi-chip-module (MCM), with multiple chips located in a single electronic package and configured to interact closely with each other through the electronic package.

Further, many embodiments are described in terms of sequences of actions or steps to be performed by specific circuits (e.g., ASICs), program instructions being executed by one or more processors, or by a combination of both. Additionally, these sequences of actions described herein can be considered to be embodied entirely in any non-transitory form of computer readable storage medium having stored therein a corresponding set of instructions that upon execution would cause an associated processor to perform the functionality described herein. Thus, the various aspects of the disclosure may be embodied in a number of different forms, which have been contemplated to be in the scope of the claimed subject matter. In addition, for each of the embodiments described herein, the corresponding form of any such embodiments may be described herein as, for example, “logic configured to” perform the described action.

The present disclosure may also be embedded in a computer program product, which includes all the features enabling the implementation of the methods described herein, and which when loaded in a computer system is able to conduct these methods. Computer program in the present context means any expression, in any language, code or notation, either statically or dynamically defined, of a set of instructions intended to cause a system having an information processing capability to perform a particular function either directly or after either or both of the following: a) conversion to another language, code or notation; b) reproduction in a different material form.

While the present disclosure has been described with reference to certain embodiments, it will be noted understood by, for example, those skilled in the art that various changes and modifications could be made and equivalents may be substituted without departing from the scope of the present disclosure as defined, for example, in the appended claims. In addition, many modifications may be made to adapt a particular situation or material to the teachings of the present disclosure without departing from its scope. The functions, steps and/or actions of the method claims in accordance with the embodiments of the disclosure described herein need not be performed in any particular order. Furthermore, although elements of the disclosure may be described or claimed in the singular, the plural is contemplated unless limitation to the singular is explicitly stated. Therefore, it is intended that the present disclosure is not limited to the embodiment disclosed, but that the present disclosure will include all embodiments falling in the scope of the appended claims.

One or more embodiments are now described with reference to the drawings, wherein like reference numerals are used to refer to like elements throughout. In the following description, for purposes of explanation, numerous specific details are set forth in order to provide a thorough understanding of the various embodiments. It is evident, however, that the various embodiments can be practiced without these specific details (and without applying to any networked environment or standard).

As used in this application, in some embodiments, the terms “component,” “system” and the like are intended to refer to, or comprise, a computer-related entity or an entity related to an operational apparatus with one or more specific functionalities, wherein the entity can be either hardware, a combination of hardware and software, software, or software in execution. As an example, a component may be, but is not limited to being, a process running on a processor, a processor, an object, an executable, a thread of execution, computer-executable instructions, a program, and/or a computer. By way of illustration and not limitation, both an application running on a server and the server can be a component.

The above descriptions and illustrations of embodiments, including what is described in the Abstract, is not intended to be exhaustive or to limit the one or more embodiments to the precise forms disclosed. While specific embodiments of, and examples for, the one or more embodiments are described herein for illustrative purposes, various equivalent modifications are possible in the scope, as those skilled in the relevant art will recognize. These modifications can be made in light of the above detailed description. Rather, the scope is to be determined by the following claims, which are to be interpreted in accordance with established doctrines of claim construction.

1. A system for optimizing a number of and locations of inspection positions of one or more physical assets in an industrial facility, comprising:
a memory for storing instructions; and
a processor configured to execute the instructions, to carry out the steps of:
generating a 3-dimensional virtual model of an industrial facility, including a plurality of virtual assets corresponding to the one or more physical assets in the industrial facility, based on data obtained from a plurality of sensors that detect and record digital data describing a mechanical condition of the one or more physical assets in the industrial facility, and a plurality of guidelines or predefined rules;
based on the plurality of guidelines or predefined rules and based on a plurality of inspection variables associated with the one or more physical assets in the industrial facility, determining a number of inspection locations in the virtual model,
further determining the number of inspection locations, one or more type of inspections and one or more corresponding positions of the inspection locations in the virtual model based on additional inspection variables to facilitate a rapid inspection by geo-locating inspection locations directly adjacent to others of the inspection locations to generate attribute data including number, types and positions of inspection locations in the virtual model by applying the plurality of guidelines or predefined rules and guidelines to automate or semi-automate naming and physical placement of the inspection locations in the virtual model;
determining a minimum or optimized number of inspection locations while meeting the plurality of guidelines or predefined rules based on one or more virtual assets adjacent to the virtual model, an accessibility index of each of the inspection locations, and a plurality of parameters associated with the plurality of guidelines or predefined rules, verifying whether the inspection locations match or deviate from the plurality of guidelines or predefined rules, generating a report that includes one or more deviations from the plurality of guidelines or predefined rules for existing inspection locations and generating a recommendation for compliance with the plurality of guidelines or rules and the plurality of inspection variables; and
rendering, at a display device associated with a client device, the generated recommendation including the optimized number of the inspection locations and the corresponding one or more positions of the inspection locations represented as a plurality of marked points,
wherein a physical inspection of the one or more physical assets is planned and executed based on the plurality of marked points; and
wherein the processor is also configured to execute instructions to further include a step of receiving user input from the client device including a user selection of one of the rendered recommendations and one or more user preferences, and executing operations to render a simulation model based on the received user input and displaying the simulation model on a display screen of the client device.

2. (canceled)

3. The system of claim 1, wherein the processor is further configured to execute instructions to further include a step of: receive the plurality of inspection variables for the virtual model based on the plurality of guidelines or predefined rules, and
wherein the plurality of inspection variables is received as data values via a user interface or collectively as a data table.

4. The system of claim 1, wherein the processor is further configured to execute instructions to further include a step of:
receive additional inspection variables corresponding to one or more attributes of the one or more physical assets,
wherein accessibility indices of the inspection locations determined based on the plurality of guidelines or predefined rules, the plurality of inspection variables, and the additional inspection variables exceed a threshold value.

5. The system of claim 1, wherein the plurality of guidelines or predefined rules includes standard operating procedures that are established based on an operational requirements of the facility and managed by one of an external agency or a regulatory agency.

6. The system of claim 1, wherein the plurality of guidelines or predefined rules relate to placement of at least one of new inspection locations or additional inspection locations in the virtual model.

7. The system of claim 1, wherein the plurality of guidelines or predefined rules relate to a review and optimization of new or existing inspection locations in the virtual model.

8. (canceled)

9. The system of claim 1, wherein the number of the inspection locations, the one or more type of inspections and the one or more corresponding positions of the inspection locations are determined based on an application of the plurality of guidelines or predefined rules to a plurality of inspection circuits or loops.

10. The system of claim 1, wherein the inspection locations correspond to one or more physical locations for Thickness Monitoring Locations (TML), Corrosion Monitoring Locations (CML) for piping and equipment, routine inspections of process equipment with gas detectors, or other points of interest in the facility.

11. A method of optimizing a number of and locations of inspection positions of one or more physical assets in an industrial facility, comprising:
generating a 3-dimensional virtual model of an industrial facility, including a plurality of virtual assets corresponding to the one or more physical assets in the industrial facility, based on data obtained from a plurality of sensors that detect and record digital data describing a mechanical condition of the one or more physical assets in the industrial facility, and a plurality of guidelines or predefined rules;
based on the plurality of guidelines or predefined rules and based on a plurality of inspection variables associated with the one or more physical assets in the industrial facility, determining a number of inspection locations in the virtual model, further determining the number of inspection locations, one or more type of inspections and one or more corresponding positions of the inspection locations in the virtual model based on additional inspection variables to facilitate a rapid inspection by geo-locating inspection locations directly adjacent to others of the inspection locations to generate attribute data including number, types and positions of inspection locations in the virtual model by applying the plurality of guidelines or predefined rules to automate or semi-automate naming and physical placement of the inspection locations in the virtual model;
determining a minimum or optimized number of inspection locations while meeting the plurality of guidelines or predefined rules based on one or more virtual assets adjacent to the virtual model, an accessibility index of each of the inspection locations, and a plurality of parameters associated with the plurality of guidelines or predefined rules, verifying whether the inspection locations match or deviate from the plurality of guidelines or predefined rules, generating a report that includes one or more deviations from the plurality of guidelines or predefined rules for existing inspection locations and generating a recommendation for compliance with the plurality of guidelines or rules and the plurality of inspection variables; and
rendering, at a display device associated with a client device, the generated recommendation including the optimized number of the inspection locations and the corresponding one or more positions of the inspection locations represented as a plurality of marked points,
wherein a physical inspection of the one or more physical assets is planned and executed based on the plurality of marked points; and
wherein the processor is also configured to execute instructions to further include a step of receiving user input from the client device including a user selection of one of the rendered recommendations and one or more user preferences, and executing operations to render a simulation model based on the received user input and displaying the simulation model on a display screen of the client device.

12. (canceled)

13. (canceled)

14. The method of claim 11, further comprising: receiving the plurality of inspection variables for the virtual model based on the plurality of guidelines or predefined rules,
wherein the plurality of inspection variables is received individually as data values via a user interface or collectively as a data table.

15. The method of claim 11, further comprising: receiving additional inspection variables corresponding to one or more attributes of the one or more physical assets,
wherein accessibility indices of the inspection locations determined based on the plurality of guidelines or predefined rules, the plurality of inspection variables, and the additional inspection variables exceed a threshold value.

16. The method of claim 11, wherein the plurality of guidelines or predefined rules relate to placement of at least one of new inspection locations or additional inspection locations in the virtual model.

17. The method of claim 11, wherein the plurality of guidelines or predefined rules relate to a review and optimization of new or existing inspection locations in the virtual model.

18. (canceled)

19. A non-transitory computer-readable medium having stored thereon, computer implemented instructions that when executed by a processor in a computer, causes the computer to execute operations, wherein the operations result in optimizing a number of and locations of inspection positions of one or more physical assets in an industrial facility, the operations comprising:
generating a 3-dimensional virtual model of an industrial facility, including a plurality of virtual assets corresponding to the one or more physical assets in the industrial facility, based on data obtained from a plurality of sensors that detect and record digital data describing a mechanical condition of the one or more physical assets in the industrial facility, and a plurality of guidelines or predefined rules;
based on the plurality of guidelines or predefined rules and based on a plurality of inspection variables associated with the one or more physical assets in the industrial facility, determining a number of inspection locations in the virtual model, further determining the number of inspection locations, one or more type of inspections and one or more corresponding positions of the inspection locations in the virtual model based on additional inspection variables to facilitate a rapid inspection by geo-locating inspection locations directly adjacent to others of the inspection locations to generate attribute data including number, types and positions of inspection locations in the virtual model by applying the plurality of guidelines or predefined rules to automate or semi-automate naming and physical placement of the inspection locations in the virtual model;
determining a minimum or optimized number of inspection locations while meeting the plurality of guidelines or predefined rules based on one or more virtual assets adjacent to the virtual model, an accessibility index of each of the inspection locations, and a plurality of parameters associated with the plurality of guidelines or predefined rules, verifying whether the inspection locations match or deviate from the plurality of guidelines or predefined rules, generating a report that includes one or more deviations from the plurality of guidelines or predefined rules for existing inspection locations and generating a recommendation for compliance with the plurality of guidelines or rules and the plurality of inspection variables; and
rendering, at a display device associated with a client device, the generated recommendation including the optimized number of the inspection locations and the corresponding one or more positions of the inspection locations represented as a plurality of marked points,
wherein a physical inspection of the one or more physical assets is planned and executed based on the plurality of marked points; and
wherein the processor is also configured to execute instructions to further include a step of receiving user input from the client device including a user selection of one of the rendered recommendations and one or more user preferences, and executing operations to render a simulation model based on the received user input and displaying the simulation model on a display screen of the client device.

20. The non-transitory computer-readable of claim 19, wherein the plurality of guidelines or predefined rules relate to a review and optimization of new or existing inspection locations in the virtual model.
